(19) United States
(12) Patent Application Publication
(10) Pub. No.: US 2026/0250124 A1
(43) Pub. Date: Aug. 27, 2026

(54) MEMS COOLING SYSTEM HAVING ENGINEERED THERMAL AND MECHANICAL CONNECTIONS

(71) Applicant: Frore Systems Inc., San Jose, CA (US)

(72) Inventors: Vikram Mukundan, San Ramon, CA (US); Suryaprakash Ganti, Los Altos, CA (US); Ananth Saran Yalamarthy, San Jose, CA (US); Prathima Kapa, Dublin, CA (US); Yu Chang Huang, Taipei (TW); ChunPin Pan, Taipei (TW); Chia Jui Lin, Taipei (TW)

(21) Appl. No.: 19/532,629

(22) Filed: Feb. 6, 2026

Related U.S. Application Data
(60) Provisional application No. 63/755,983, filed on Feb. 7, 2025.

(51) Int. Cl. B81B 7/00

(52) U.S. Cl. CPC B81B 7/0093

(57) ABSTRACT

A system including a vibrational air transfer device and a heat spreader is described. The vibrational air transfer device extends in space and defines a plane. The vibrational air transfer device is thermally and mechanically coupled to the heat spreader. The mechanical coupling allows the vibrational air transfer device to tilt with respect to the plane about at least one axis and damps translation of the vibrational air transfer device with respect to the heat spreader.

### CROSS REFERENCE TO OTHER APPLICATIONS

This application claims priority to U.S. Provisional Patent Application No. 63/755,983 entitled MEMS COOLING SYSTEM HAVING ENGINEERED THERMAL AND MECHANICAL CONNECTIONS filed February 07, 2025 which is incorporated herein by reference for all purposes.

### BACKGROUND OF THE INVENTION

As computing devices grow in speed and computing power, the heat generated by the computing devices also increases. Various mechanisms have been proposed to address the generation of heat. Active devices, such as fans, may be used to drive air through larger computing devices, such as laptop computers or desktop computers. Passive cooling devices, such as heat spreaders, may be used in smaller, mobile computing devices, such as smartphones, virtual reality devices and tablet computers. However, such active and passive devices may be unable to adequately cool mobile devices, larger (e.g., desk top) devices, and/or high power computing systems, such as server systems. In addition to the ability to cool the other aspects of the cooling system may also be desirable. For example, the cooling system is desired to be robust. For Consequently, additional cooling solutions for computing devices, particularly high power dissipation computing devices, are desired.

### BRIEF DESCRIPTION OF THE DRAWINGS

Various embodiments of the invention are disclosed in the following detailed description and the accompanying drawings.

FIGS. 1A-1G depict an embodiment of an active MEMS cooling system including a centrally anchored cooling element.

FIGS. 2A-2B depict an embodiment of an active MEMS cooling system including a centrally anchored cooling element.

FIGS. 3A-3E depict an embodiment of an active MEMS cooling system formed in a tile.

FIGS. 4A-4C depict an embodiment of an active MEMS cooling system including a vibrational air transfer device thermally and mechanically coupled to a heat spreader.

FIGS. 5A-5D depict embodiments of an active MEMS cooling system including a vibrational air transfer device thermally and mechanically coupled to a heat spreader.

FIGS. 6A-6B depict an embodiment of an active MEMS cooling system including a vibrational air transfer device thermally and mechanically coupled to a heat spreader.

FIGS. 7A-7B depict an embodiment of an active MEMS cooling system including a vibrational air transfer device thermally and mechanically coupled to a heat spreader.

FIG. 8 depicts an embodiment of an active MEMS cooling system including a vibrational air transfer device thermally and mechanically coupled to a heat spreader.

FIG. 9 depicts an embodiment of an active MEMS cooling system including a vibrational air transfer device thermally and mechanically coupled to a heat spreader.

FIG. 10 depicts an embodiment of an active MEMS cooling system including a vibrational air transfer device thermally and mechanically coupled to a heat spreader.

FIG. 11 depicts an embodiment of an active MEMS cooling system including a vibrational air transfer device thermally and mechanically coupled to a heat spreader.

FIG. 12 depicts an embodiment of an active MEMS cooling system including a vibrational air transfer device thermally and mechanically coupled to a heat spreader.

FIGS. 13A-13C depict an embodiment of an active MEMS cooling system including a vibrational air transfer device thermally and mechanically coupled to a heat spreader.

FIGS. 14A-14C depict an embodiment of an active MEMS cooling system including a vibrational air transfer device thermally and mechanically coupled to a heat spreader.

FIG. 15 is a flow chart depicting an embodiment of a method for using an active MEMS cooling system including a vibrational air transfer device thermally and mechanically coupled to a heat spreader.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As computing devices continue to increase in speed and processing capability, they generate correspondingly greater amounts of heat. Active cooling mechanisms, such as fans, are commonly employed in larger systems including laptops and desktops, while passive approaches, such as heat spreaders, are typically utilized in smaller mobile devices. Nonetheless, these methods may prove inadequate for mobile platforms, high-performance desktops, or server-class systems. Moreover, cooling mechanisms must also demonstrate sufficient robustness. For example, mobile devices may be dropped or undergo other shocks during use. Similarly, electronic devices mounted in vehicles may also experience significant forces on small time scales, for example in the case of an accident. It is desirable for cooling solutions for such devices to retain operability after such shocks. Consequently, there remains a need for enhanced and more robust cooling solutions capable of supporting high-power-dissipation computing devices.

A system including a vibrational air transfer device and a heat spreader is described. The vibrational air transfer device extends in space and defines a plane. The vibrational air transfer device is thermally and mechanically coupled to the heat spreader. The mechanical coupling allows the vibrational air transfer device to tilt with respect to the plane about at least one axis and damps translation of the vibrational air transfer device with respect to the heat spreader.

In some embodiments, the plane is defined by the vibrational air transfer device in a static configuration. The mechanical coupling may restrict the vibrational air transfer device from tilting around at least one of a second axis at a first nonzero angle from the first axis or a third axis at a second nonzero angle from the axis. For example, the vibrational air transfer device may be allowed to tilt around a first axis, but a yaw (tilt around a second axis perpendicular to the first axis) and/or a pitch (tilt around a third axis perpendicular to the first and second axes) may be restricted.

The plane defined by the vibrational air transfer device may not be a perfect, mathematical plane. The plane may be irregularly shaped and have a topography. For example, the plane may be defined by the vibrational air transfer device in a static configuration when not being operated (e.g., actuators are not energized) and not undergoing external shocks (e.g. not being dropped). In some embodiments, the mechanical coupling also restricts the vibrational air transfer device from tilting around a second and/or third axis. For example, if the tile may be viewed as roll around the first axis, then pitch around the second axis (that may be perpendicular to the first axis) and/or yaw around the third axis (that may be perpendicular to the first axis and/or the second axis) may be damped or otherwise restricted. In some embodiments, translation parallel and/or perpendicular to the plane is/are damped.

In some embodiments, the vibrational air transfer device is supported and coupled to the heat spreader by a support structure that allows the vibrational air transfer device to tilt with respect to the plane about the at least one axis and damps the translation with respect to the heat spreader. The support structure is thermally conductive in some embodiments. The support structure may include a pedestal. In some embodiments, the support structure may include at least one of bumper(s), spring(s) and/or fillet(s) in addition to the pedestal. The bumper(s), spring(s) and/or fillet(s) may include or consist of material(s) having a Shore A hardness of at least A20 and not more than A60. In some embodiments, the mechanical coupling between the heat spreader and the vibrational air transfer devices allows for the system to withstand forces of at least 400 g, where g is the earth’s surface gravity.

The vibrational air transfer device may include a chamber having an actuator therein. The actuator vibrates around an actuator axis substantially parallel to the at least one axis around which the vibrational air transfer device may tilt.

A system including a vibrational air transfer device, a heat spreader, pedestals, and mechanical supporting structures is described. The vibrational air transfer device extends in space and defines a plane. The vibrational air transfer device includes a plurality of chambers, each of which has a cooling element therein. The pedestals couple the vibrational air transfer device to the heat spreader. The mechanical supporting structures are coupled with the pedestals and the heat spreader. The pedestals and the mechanical supporting structures allow the vibrational air transfer device to tilt with respect to the plane about at least one axis and damp translation of the vibrational air transfer device with respect to the heat spreader. The cooling element vibrates around a cooling element axis parallel to the at least one axis. In some embodiments, the system includes a plurality of additional mechanical supporting structures coupled with the vibrational air transfer device and the heat spreader. The additional mechanical supporting structures allow the vibrational air transfer device to tilt with respect to the plane about the at least one axis and damp translation of the vibrational air transfer device with respect to the heat spreader.

In some embodiments, the plane is defined by the vibrational air transfer device in a static configuration. In some embodiments, the pedestals and the mechanical supporting structures allow vibrational air transfer device to tilt by not more than thirty degrees around the at least one axis and restrict the vibrational air transfer device from pitching and yawing from the at least one axis. In some embodiments, at least one of the pedestals and/or the mechanical supporting structures are thermally conductive. The mechanical supporting structures may each have a hardness of at least A20 and not more than A60 on the Shore A hardness scale. In some embodiments, the pedestals and the mechanical supporting structures allow for the system to withstand forces of at least 400 multiplied by the gravity of the earth proximate to the earth’s surface.

A method is described. The method includes driving an active element of a vibrational air transfer device to induce a vibrational motion at a frequency. The vibrational motion drives fluid through the vibrational air transfer device. The vibrational air transfer device extends in space and defines a plane. The vibrational air transfer device is thermally and mechanically coupled to a heat spreader. The mechanical coupling allows the vibrational air transfer device to tilt with respect to the plane, about at least one axis, and damps translation with respect to the heat spreader. In some embodiments, the mechanical coupling restricts the vibrational air transfer device from tilting around at least one of a second axis at a first nonzero angle from the first axis or a third axis at a second nonzero angle from the axis. The mechanical coupling between the heat spreader and the vibrational air transfer device may allow for a connection between the heat spreader and the vibrational air transfer device to withstand forces of at least 400 multiplied by g, where g is a surface gravity force of earth.

In some embodiments, the vibrational air transfer device is supported near a central region to allow the tilting. The support structure is thermally conductive. For example, a pedestal may provide a support structure for the vibrational air transfer device. The pedestal may be formed of thermally conductive adhesives such as epoxy or silicone. In such embodiments, the tilt allowed by mechanical coupling is rotation around the axis corresponding to pedestal(s). The pedestal(s) may be central connection(s) between the vibrational air transfer device (e.g. central to a tile of the vibrational air transfer device or central to the entire vibrational air transfer device) and the heat spreader. The mechanical coupling may include the pedestal itself. The mechanical coupling may also include at least one of fillet(s) proximate to the pedestal(s), bumper(s) near the edges or corners of the vibrational air transfer device that couple the vibrational air transfer device to the heat spreader, and/or spring(s). The springs may be used in addition to or in lieu of the pedestal. In some embodiments, the bumper(s), fillet(s), and/or spring(s) may be thermally conductive. In some embodiments, the mechanical coupling between the heat spreader and the vibrational air transfer devices allows for the system to withstand forces (e.g. shocks) of at least 200 g (g = earth’s gravity), 300 g, 400 g, 500 g, 600 g, 700g, 800g, 900g, 1000g, 1300g, 1500g, or 2000 g. In some embodiments, the mechanical coupling allows the heat spreader and the vibrational air transfer device to withstand forces (e.g. shocks) of not more than 500g, 1000g, 2000g, or 5000g).

In some embodiments, each tile may include one or more cooling cells. Each cooling cell may be analogous to the cooling cells described herein. For example, a tile may include four cooling cells. The vibrational air transfer device may include one or more tiles. In some embodiments, the vibrational air transfer device may include another number of cooling cells (e.g. one cooling cell, two cooling cells, three cooling cells, five cooling cells, and so on). Other configurations of cooling cells and/or other cooling cells may be used in some embodiments.

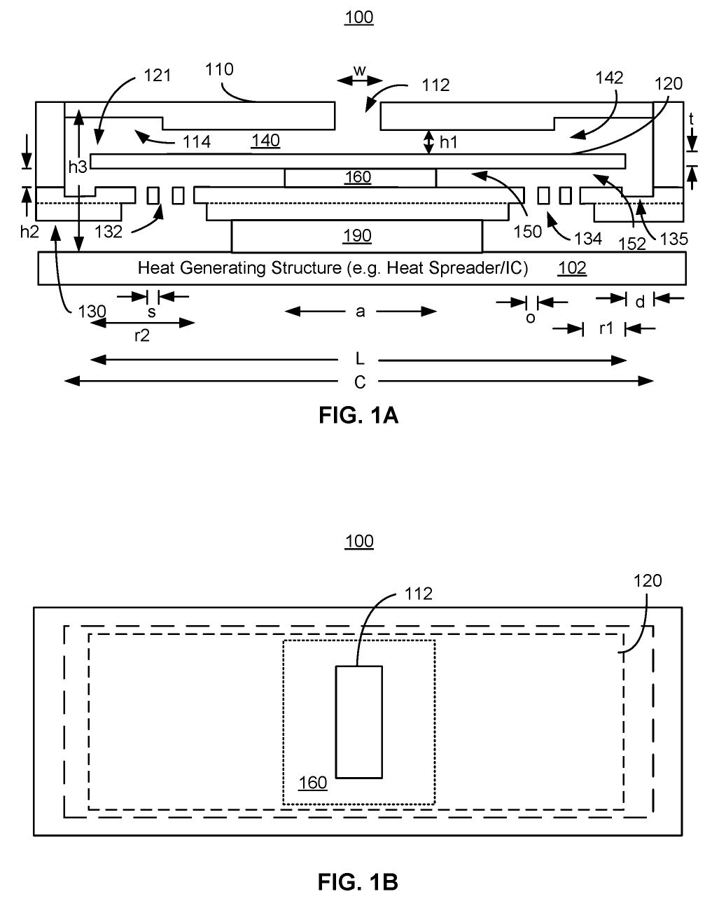

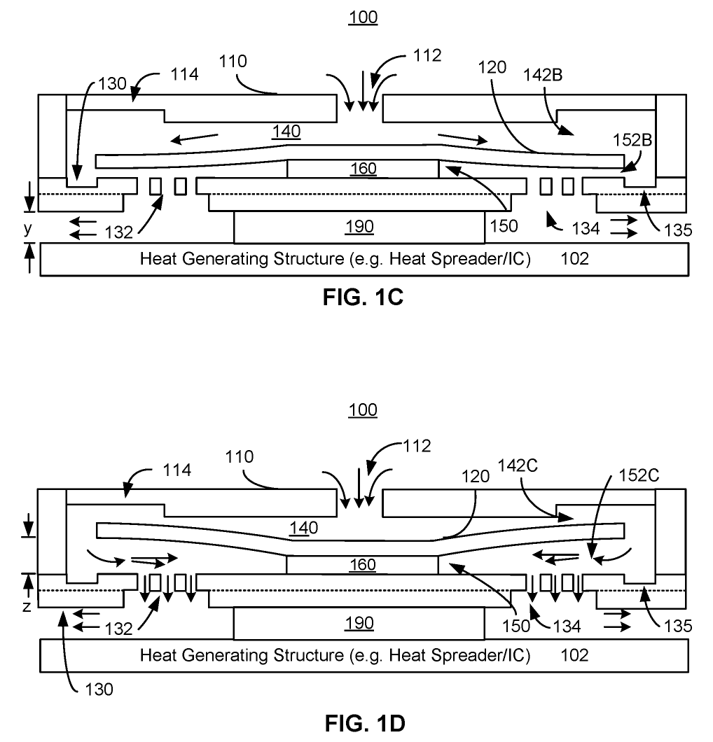

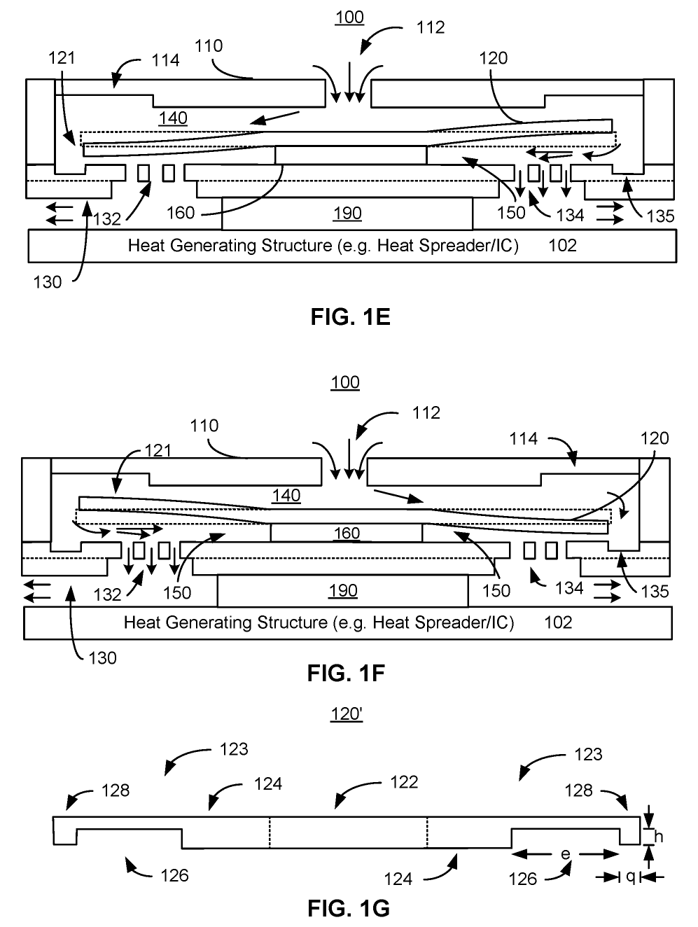

FIGS. 1A-1G are diagrams depicting an exemplary embodiment of active MEMS cooling system 100 usable with heat-generating structure 102 and including a centrally anchored cooling element 120 or 120’. Although termed a cooling system, MEMS system 100 and analogous systems described herein may be considered heat transfer systems and/or fluid transfer systems. Cooling element 120 is shown in FIGS. 1A-1F and cooling element 120’ is shown in FIG. 1G. For clarity, only certain components are shown. FIGS. 1A-1G are not to scale. FIGS. 1A and 1B depict cross-sectional and top views of cooling system 100 in a neutral position. FIGS. 1C-1D depict cooling system 100 during actuation for in-phase vibrational motion. FIGS. 1E-1F depict cooling system 100 during actuation for out-of-phase vibrational motion. Although shown as symmetric, cooling system 100 need not be.

Cooling system 100 includes top plate 110 having vent 112 and cavities 114 therein, cooling element 120, orifice plate 130 having orifices 132 and cavities 134 and 135 therein, support structure (or “anchor”) 160 and chambers 140 and 150 (collectively chamber 140/150) formed therein. Cooling element 120 is supported at its central region by anchor 160. Although termed a cooling element with respect to FIGS. 1A-1G, cooling element 120 and analogous elements described herein may also be considered actuators, vibrating elements, vibrating components, active components, active elements, and/or other terms indicating that the element is configured to undergo vibrational motion when activated (or energized) and/or to drive fluid through a system. Regions of cooling element 120 closer to and including portions of the cooling element’s perimeter (e.g. tip 121) vibrate when actuated. In some embodiments, tip 121 of cooling element 120 includes a portion of the perimeter furthest from anchor 160 and undergoes the largest deflection during actuation of cooling element 120. For clarity, only one tip 121 of cooling element 120 is labeled in FIG. 1A. In some embodiments, vibration of portions of cooling element 120 may cause motion (e.g. rotation) of anchor 160. Also shown is pedestal 190 that connects orifice plate 130 to and offsets orifice plate 130 from heat-generating structure 102. In some embodiments, pedestal 190 also thermally couples orifice plate 130 to heat-generating structure 102. In some embodiments, orifice plate 130 may include an upper plate and a lower, jet channel plate. This is indicated by the dashed line in orifice plate 130. Thus, multiple plates and/or plate(s) having various structures may be used at the bottom plate for cooling system 100.

FIG. 1A depicts cooling system 100 in a neutral position. Thus, cooling element 120 is shown as substantially flat. For in-phase operation, cooling element 120 is driven to vibrate between positions shown in FIGS. 1C and 1D. This vibrational motion draws fluid (e.g. air) into vent 112, through chambers 140 and 150 and out orifices 132 at high speed and/or flow rates. The geometry of cooling system 100 may be configured to achieve particular speeds and/or flow rates may for various applications and fluids. For example, the speed at which the fluid (e.g., air) is driven toward heat-generating structure 102 may be at least ten meters per second. In some embodiments, the flow rate through cooling system 100 may be up to approximately 0.08 cubic feet per minute (e.g., at least 0.04 or 0.05 and not more than 0.08 cfm) for air. In some embodiments, the speed may be at least thirty meters per second (e.g. exiting orifices 132 or through the small gap 152B). In some embodiments, the fluid is driven by cooling element 120 toward heat-generating structure 102 at a speed of at least forty-five meters per second. In some embodiments, the fluid is driven toward heat-generating structure 102 by cooling element 120 at speeds of at least sixty meters per second. Other speeds may be possible in some embodiments. Cooling system 100 is also configured so that little or no fluid is drawn back into chamber 140/150 through orifices 132 by the vibrational motion of cooling element 120.

Heat-generating structure 102 is desired to be cooled by cooling system 100. In some embodiments, heat-generating structure 102 generates heat. For example, heat-generating structure may be an integrated circuit. In some embodiments, heat-generating structure 102 is desired to be cooled but does not generate heat itself. Heat-generating structure 102 may conduct heat (e.g. from a nearby object that generates heat). For example, heat-generating structure 102 might be a heat spreader or a vapor chamber. Thus, heat-generating structure 102 may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. In some embodiments, heat-generating structure 102 may be a thermally conductive part of a module containing cooling system 100. For example, cooling system 100 may be affixed to heat-generating structure 102, which may be coupled to another heat spreader, a heat sink, vapor chamber, integrated circuit, or other separate structure desired to be cooled.

The devices in which cooling system 100 is desired to be used may also have limited space in which to place a cooling system. For example, cooling system 100 may be used in computing devices. Such computing devices may include but are not limited to smartphones, tablet computers, laptop computers, tablets, two-in-one laptops, hand held gaming systems, digital cameras, virtual reality headsets, augmented reality headsets, mixed reality headsets and other devices that are thin. Cooling system 100 may be a micro-electro-mechanical system (MEMS) cooling system capable of residing within mobile computing devices and/or other devices having limited space in at least one dimension. For example, the total height, h3, of cooling system 100 (from the top of heat-generating structure 102 to the top of top plate 110) may be less than 2 millimeters. In some embodiments, the total height of cooling system 100 is not more than 1.5 millimeters. In some embodiments, this total height is not more than 1.1 millimeters. In some embodiments, the total height does not exceed one millimeter. In some embodiments, the total height does not exceed two hundred and fifty micrometers. Similarly, the distance between the bottom of orifice plate 130 and the top of heat-generating structure 102, y, may be small. In some embodiments, y is at least two hundred micrometers and not more than 1.2 millimeters. For example, y may be at least two hundred and fifty micrometers and not more than three hundred micrometers. In some embodiments, y is at least five hundred micrometers and not more than one millimeter. In some embodiments, y is at least two hundred micrometers and not more than three hundred micrometers. Thus, cooling system 100 is usable in computing devices and/or other devices having limited space in at least one dimension. However, nothing prevents the use of cooling system 100 in devices having fewer limitations on space and/or for purposes other than cooling. Although one cooling system 100 is shown (e.g. one cooling cell), multiple cooling systems 100 might be used in connection with heat-generating structure 102. For example, a one or two-dimensional array of cooling cells might be utilized.

Cooling system 100 is in communication with a fluid used to cool heat-generating structure 102. The fluid may be a gas and/or a liquid. For example, the fluid may be air, air combined with liquid vapor, or a liquid. In some embodiments, the fluid includes fluid from outside of the device in which cooling system 100 resides (e.g. provided through external vents in the device). In some embodiments, the fluid circulates within the device in which cooling system 100 resides (e.g. in an enclosed device).

Cooling element 120 can be considered to divide the interior of active MEMS cooling system 100 into top chamber 140 and bottom chamber 150. Top chamber 140 is formed by cooling element 120, the sides, and top plate 110. Bottom chamber 150 is formed by orifice plate 130, the sides, cooling element 120 and anchor 160. Top chamber 140 and bottom chamber 150 are connected at the periphery of cooling element 120 and together form chamber 140/150 (e.g. an interior chamber of cooling system 100).

The size and configuration of top chamber 140 may be a function of the cell (cooling system 100) dimensions, cooling element 120 motion, and the frequency of operation. Top chamber 140 has a height, h1. The height of top chamber 140 may be selected to provide sufficient pressure to drive the fluid to bottom chamber 150 and through orifices 132 at the desired flow rate and/or speed. Top chamber 140 is also sufficiently tall that cooling element 120 does not contact top plate 110 when actuated. The magnitude of the deflection of cooling element 120 may also be tailored by, for example, changing the driving voltage of the signal used to drive vibration of cooling element 120. In some embodiments, the height of top chamber 140 is at least fifty micrometers and not more than five hundred micrometers. In some embodiments, top chamber 140 has a height of at least two hundred and not more than three hundred micrometers.

Bottom chamber 150 has a height, h2. In some embodiments, the height of bottom chamber 150 is sufficient to accommodate the motion of cooling element 120. For example, the height of bottom chamber 150 may be sufficiently large to accommodate the maximum amplitude of vibration of cooling element 120. Thus, no portion of cooling element 120 contacts orifice plate 130 during normal operation in some embodiments. Bottom chamber 150 is generally smaller than top chamber 140 and may aid in reducing the backflow of fluid into orifices 132. In some embodiments, the height of bottom chamber 150 is the maximum deflection of cooling element 120 plus at least five micrometers and not more than ten micrometers. In some embodiments, the deflection of cooling element 120 (e.g. the deflection of tip 121), z, has an amplitude of at least ten micrometers and not more than one hundred micrometers. In some such embodiments, the amplitude of deflection of cooling element 120 is at least ten micrometers and not more than sixty micrometers. However, the amplitude of deflection of cooling element 120 depends on factors such as the desired flow rate through cooling system 100 and the configuration of cooling system 100. Thus, the height of bottom chamber 150 generally depends on the flow rate through and other components of cooling system 100.

Top plate 110 includes vent 112 through which fluid may be drawn into cooling system 100. Top vent 112 may have a size chosen based on the desired acoustic pressure in chamber 140. For example, in some embodiments, the width, w, of vent 112 is at least five hundred micrometers and not more than one thousand micrometers. In some embodiments, the width of vent 112 is at least two hundred fifty micrometers and not more than two thousand micrometers. In the embodiment shown, vent 112 is a centrally located aperture in top plate 110. In other embodiments, vent 112 may be located elsewhere. For example, vent 112 may be closer to one of the edges of top plate 110. Vent 112 may have a circular, rectangular or other shaped footprint. Although a single vent 112 is shown, multiple vents might be used. For example, vents may be offset toward the edges of top chamber 140 or be located on the side(s) of top chamber 140. Top plate 110 also includes cavities 114 therein. Cavities 114 may facilitate vibration of cooling element 120 by moderating the pressure variation near tip of cooling element 120. In other embodiments, cavities 114 may be omitted and top plate 110 may be substantially flat. In some embodiments, other and/or additional trenches and/or other structures may be provided in top plate 110 to modify the configuration of top chamber 140 and/or the region above top plate 110.

Anchor (support structure) 160 supports cooling element 120 at the central portion of cooling element 120. Thus, at least part of the perimeter of cooling element 120 is unpinned and free to vibrate. In some embodiments, anchor 160 extends along a central axis of cooling element 120 (e.g. perpendicular to the page in FIGS. 1A and 1C-1F). In such embodiments, portions of cooling element 120 that vibrate (e.g. including tip 121) move in a cantilevered fashion. Thus, portions of cooling element 120 may move in a manner analogous to the wings of a butterfly (i.e. in phase) and/or analogous to a see-saw (i.e. out of phase). Thus, the portions of cooling element 120 that vibrate in a cantilevered fashion do so in phase in some embodiments and out of phase in other embodiments. In some embodiments, anchor 160 does not extend along an axis of cooling element 120. In such embodiments, all portions of the perimeter of cooling element 120 are free to vibrate (e.g. analogous to a jellyfish). In the embodiment shown, anchor 160 supports cooling element 120 from the bottom of cooling element 120. In other embodiments, anchor 160 may support cooling element 120 in another manner. For example, anchor 160 may support cooling element 120 from the top (e.g. cooling element 120 hangs from anchor 160). In some embodiments, the width, a, of anchor 160 is at least 0.5 millimeters and not more than four millimeters. In some embodiments, the width of anchor 160 is at least two millimeters and not more than 2.5 millimeters. Anchor 160 may occupy at least ten percent and not more than fifty percent of cooling element 120.

Cooling element 120 has a first side distal from heat-generating structure 102 and a second side proximate to heat-generating structure 102. In the embodiment shown in FIGS. 1A and 1C-1F, the first side of cooling element 120 is the top of cooling element 120 (closer to top plate 110) and the second side is the bottom of cooling element 120 (closer to orifice plate 130). Cooling element 120 is actuated to undergo vibrational motion as shown in FIGS. 1A and 1C-1F. The vibrational motion of cooling element 120 drives fluid from the first side of cooling element 120 distal from heat-generating structure 102 (e.g. from top chamber 140) to a second side of cooling element 120 proximate to heat-generating structure 102 (e.g. to bottom chamber 150). The vibrational motion of cooling element 120 also draws fluid through vent 112 and into top chamber 140; forces fluid from top chamber 140 to bottom chamber 150; and drives fluid from bottom chamber 150 through orifices 132 of orifice plate 130. Thus, cooling element 120 may be viewed as an actuator. Although described in the context of a single, continuous cooling element, in some embodiments, cooling element 120 may be formed by two (or more) cooling elements. Each of the cooling elements is depicted as one portion pinned (e.g. supported by support structure 160) and an opposite portion unpinned. Thus, a single, centrally supported cooling element 120 may be formed by a combination of multiple cooling elements supported at an edge.

Cooling element 120 has a length, L, that depends upon the frequency at which cooling element 120 is desired to vibrate. In some embodiments, the length of cooling element 120 is at least four millimeters and not more than ten millimeters. In some such embodiments, cooling element 120 has a length of at least six millimeters and not more than eight millimeters. The depth of cooling element 120 (e.g. perpendicular to the plane shown in FIGS. 1A and 1C-1F) may vary from one fourth of L through twice L. For example, cooling element 120 may have the same depth as length. The thickness, t, of cooling element 120 may vary based upon the configuration of cooling element 120 and/or the frequency at which cooling element 120 is desired to be actuated. In some embodiments, the cooling element thickness is at least two hundred micrometers and not more than three hundred and fifty micrometers for cooling element 120 having a length of eight millimeters and driven at a frequency of at least twenty kilohertz and not more than twenty-five kilohertz. The length, C, of chamber 140/150 is close to the length, L, of cooling element 120. For example, in some embodiments, the distance, d, between the edge of cooling element 120 and the wall of chamber 140/150 is at least one hundred micrometers and not more than five hundred micrometers. In some embodiments, d is at least two hundred micrometers and not more than three hundred micrometers.

Cooling element 120 may be driven at a frequency that is at or near both the resonant frequency for an acoustic resonance of a pressure wave of the fluid in top chamber 140 and the resonant frequency for a structural resonance of cooling element 120. The portion of cooling element 120 undergoing vibrational motion is driven at or near resonance (the “structural resonance”) of cooling element 120. This portion of cooling element 120 undergoing vibration may be a cantilevered section. The frequency of vibration for structural resonance is termed the structural resonant frequency. Use of the structural resonant frequency in driving cooling element 120 reduces the power consumption of cooling system 100. Cooling element 120 and top chamber 140 may also be configured such that this structural resonant frequency corresponds to a resonance in a pressure wave in the fluid being driven through top chamber 140 (the acoustic resonance of top chamber 140). The frequency of such a pressure wave is termed the acoustic resonant frequency. At acoustic resonance, a node in pressure occurs near vent 112 and an antinode in pressure occurs near the periphery of cooling system 100 (e.g. near tip 121 of cooling element 120 and near the connection between top chamber 140 and bottom chamber 150). The distance between these two regions is C/2. Thus, C/2 = nl/4, where l is the acoustic wavelength for the fluid and n is odd (e.g. n = 1, 3, 5, etc.). For the lowest order mode, C = l/2. Because the length of chamber 140 (e.g. C) is close to the length of cooling element 120, in some embodiments, it is also approximately true that L/2 = nl/4, where l is the acoustic wavelength for the fluid and n is odd. Thus, the frequency at which cooling element 120 is driven, n, is at or near the structural resonant frequency for cooling element 120. The frequency n is also at or near the acoustic resonant frequency for at least top chamber 140. The acoustic resonant frequency of top chamber 140 generally varies less dramatically with parameters such as temperature and size than the structural resonant frequency of cooling element 120. Consequently, in some embodiments, cooling element 120 may be driven at (or closer to) a structural resonant frequency rather than to the acoustic resonant frequency.

Orifice plate 130 has orifices 132 and cavities 134 and 135 therein. Although a particular number and distribution of orifices 132 and cavities 134 and 135 are shown, another number and/or another distribution may be used. Cavities 134 and/or 135 may be configured differently or may be omitted. In some embodiments, other cavities may be within flow chamber 140/150 or the jet channel between orifice plate 130 and heat-generating structure 102. Cavity 135 may assist in capturing dust entering flow chamber 140/150 and/or may enhance fluid flow. A single orifice plate 130 is used for a single cooling system 100. In other embodiments, multiple cooling systems 100 may share an orifice plate. For example, multiple cells 100 may be provided together in a desired configuration. In such embodiments, the cells 100 may be the same size and configuration or different size(s) and/or configuration(s). Orifices 132 are shown as having an axis oriented normal to a surface of heat-generating structure 102. In other embodiments, the axis of one or more orifices 132 may be at another angle. For example, the angle of the axis may be from substantially zero degrees through a nonzero acute angle from normal to the surface. Orifices 132 also have sidewalls that are substantially parallel to the normal to the surface of orifice plate 130. In some embodiments, orifices may have sidewalls at a nonzero angle to the normal to the surface of orifice plate 130. For example, orifices 132 may be cone-shaped. Further, although orifice place 130 is shown as having a particular configuration, other configurations are possible.

The size, number, distribution, and locations of orifices 132 are chosen to control the flow rate of fluid driven to the surface of heat-generating structure 102. The locations and configurations of orifices 132 may be configured to increase the fluid flow from bottom chamber 150 through orifices 132 to the jet channel (the region between the bottom of orifice plate 130 and the top of heat-generating structure 102). The locations and configurations of orifices 132 may also be selected to reduce the suction flow (e.g. back flow) from the jet channel through orifices 132. For example, the locations of orifices are desired to be sufficiently far from tip 121 that suction in the upstroke of cooling element 120 (tip 121 moves away from orifice plate 130) that would pull fluid into bottom chamber 150 through orifices 132 is reduced. The locations of orifices are also desired to be sufficiently close to tip 121 that suction in the upstroke of cooling element 120 also allows a higher pressure from top chamber 140 to push fluid from top chamber 140 into bottom chamber 150. In some embodiments, the ratio of the flow rate from top chamber 140 into bottom chamber 150 to the flow rate from the jet channel through orifices 132 (the “net flow ratio”) is greater than 2:1. In some embodiments, the net flow ratio is at least 85:15. In some embodiments, the net flow ratio is at least 90:10. In order to provide the desired pressure, flow rate, suction, and net flow ratio, orifices 132 may be desired to be at least a distance, r1, from tip 121 and not more than a distance, r2, from tip 121 of cooling element 120. In some embodiments, r1 is at least one hundred micrometers (e.g. r1 ≥ 100 mm) and r2 is not more than one millimeter (e.g. r2 ≤ 1000 mm). In some embodiments, orifices 132 are at least two hundred micrometers from tip 121 of cooling element 120 (e.g. r1 ≥ 200 mm). In some such embodiments, orifices 132 are at least three hundred micrometers from tip 121 of cooling element 120 (e.g. r1 ≥ 300 mm). In some embodiments, orifices 132 have a width, o, of at least one hundred micrometers and not more than five hundred micrometers. In some embodiments, orifices 132 have a width of at least two hundred micrometers and not more than three hundred micrometers. In some embodiments, the orifice separation, s, is at least one hundred micrometers and not more than one millimeter. In some such embodiments, the orifice separation is at least four hundred micrometers and not more than six hundred micrometers. In some embodiments, orifices 132 are also desired to occupy a particular fraction of the area of orifice plate 130. For example, orifices 132 may cover at least five percent and not more than fifteen percent of the footprint of orifice plate 130 in order to achieve a desired flow rate of fluid through orifices 132. In some embodiments, orifices 132 cover at least eight percent and not more than twelve percent of the footprint of orifice plate 130.

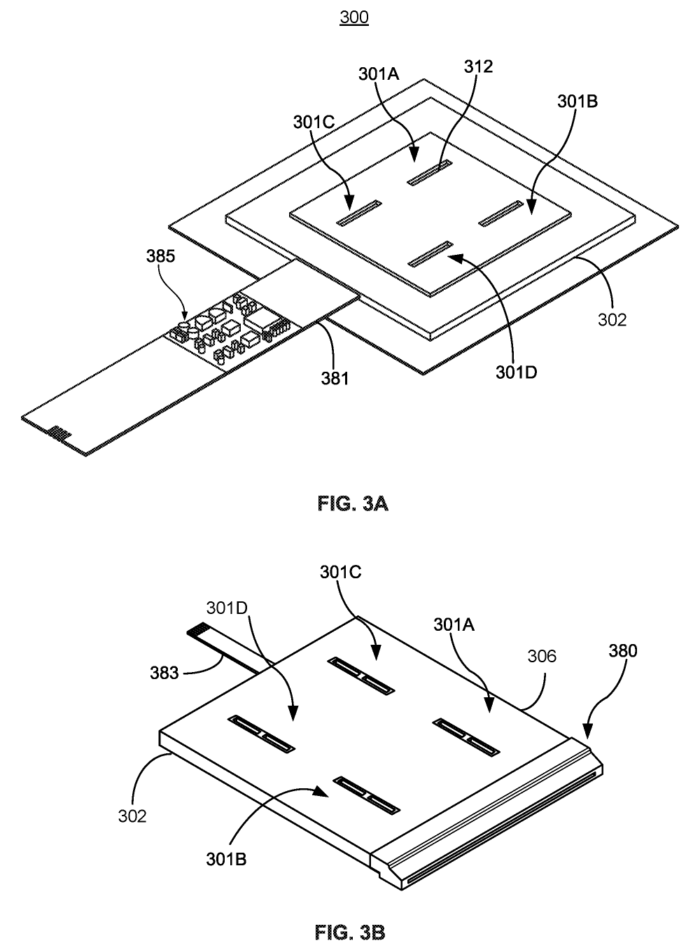

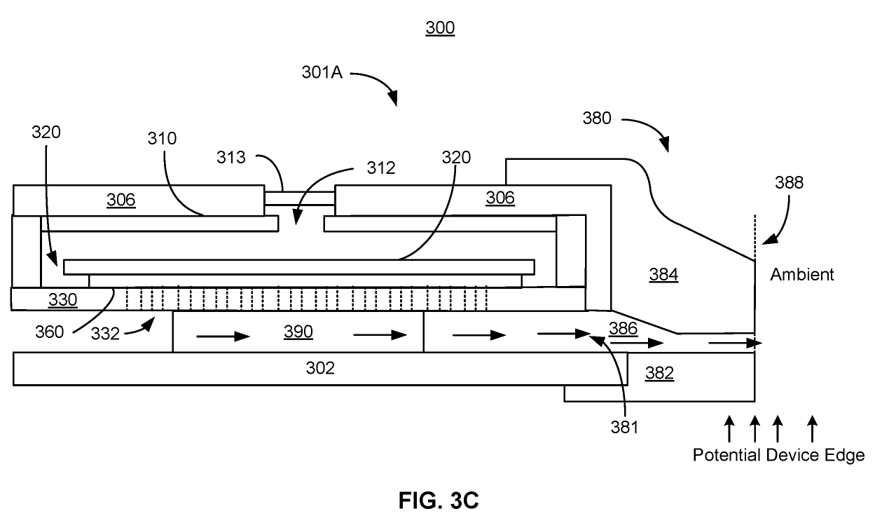

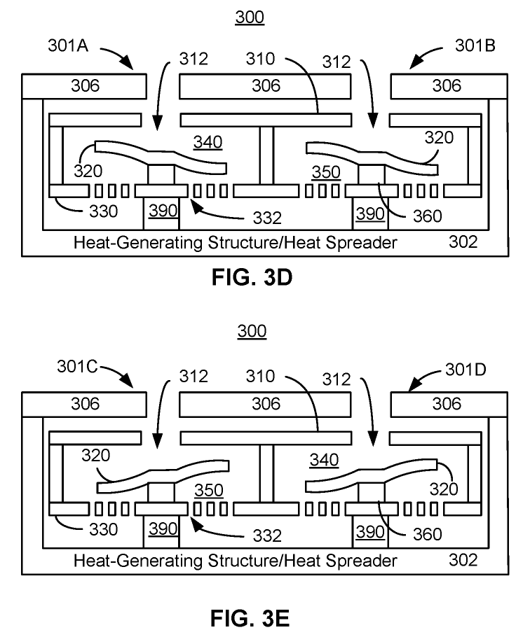

In some embodiments, cooling element 120 is actuated using a piezoelectric material. Cooling element 120 may be driven by a piezoelectric material that is mounted on or integrated into cooling element 120. In some embodiments, cooling element 120 is driven in another manner including but not limited to providing a piezoelectric material on another structure in cooling system 100. Cooling element 120 and analogous cooling elements may be referred to hereinafter as piezoelectric cooling elements though it is possible that a mechanism other than a piezoelectric material might be used to drive the cooling element. In some embodiments, cooling element 120 includes a piezoelectric layer on substrate. The substrate may include or consist of stainless steel, a Ni alloy, Hastelloy, Al (e.g. an Al alloy), and/or Ti (e.g. a Ti alloy such as Ti6Al-4V). For example, in some embodiments, the substrate may include or consist of grade 2 Ti. Orifice plate 130 may be formed of the same material as the substrate. For example, orifice plate 130 may include or consist of grade 2 Ti. Top plate 110 and surrounding structures such as structure 306 in FIGS. 3A-3E may be formed of a stainless steel such as SUS430. SUS430 or an analogous material may be selected to better match the coefficient of thermal expansion of the substrate and/or orifice plate 130. In some embodiments, orifice plate 130 is diffusion bonded to the substrate and/or anchor 160. In some embodiments, a piezoelectric layer includes multiple sublayers formed as thin films on the substrate. In other embodiments, the piezoelectric layer may be a bulk layer affixed to the substrate. Such a piezoelectric cooling element 120 also includes electrodes used to activate the piezoelectric material. The substrate functions as an electrode in some embodiments. In other embodiments, a bottom electrode may be provided between the substrate and the piezoelectric layer. Other layers including but not limited to seed, capping, passivation, or other layers might be included in the piezoelectric cooling element. Thus, cooling element 120 may be actuated using a piezoelectric material.

In some embodiments, cooling system 100 includes chimneys (not shown) and/or other ducting. Such ducting provides a path for heated fluid to flow away from heat-generating structure 102. In some embodiments, ducting returns fluid to the side of top plate 110 distal from heat-generating structure 102. In some embodiments, ducting may instead direct fluid away from heat-generating structure 102. For example, in a device in which fluid external to the device is used in cooling system 100, the ducting may channel the heated fluid to a vent. In such embodiments, additional fluid may be provided from an inlet vent. In embodiments in which the device is enclosed, the ducting may provide a circuitous path back to the region near vent 112 and distal from heat-generating structure 102. Such a path allows for the fluid to dissipate heat before being reused to cool heat-generating structure 102. In other embodiments, ducting may be omitted or configured in another manner. Thus, the fluid is allowed to carry away heat from heat-generating structure 102.

Operation of cooling system 100 is described in the context of FIGS. 1A and 1C-1F. Although described in the context of particular pressures, gap sizes, and timing of flow, operation of cooling system 100 is not dependent upon the explanation herein. FIGS. 1C-1D depict in-phase operation of cooling system 100. Referring to FIG. 1C, cooling element 120 has been actuated so that its tip 121 moves away from top plate 110. FIG. 1C can thus be considered to depict the end of a down stroke of cooling element 120. Because of the vibrational motion of cooling element 120, gap 152 for bottom chamber 150 has decreased in size and is shown as gap 152B. Conversely, gap 142 for top chamber 140 has increased in size and is shown as gap 142B. Because top chamber 140 increases in size, a lower pressure is present in top chamber 140. Because bottom chamber 150 has decreased in size, a higher pressure is present at gap 152B.

Cooling element 120 is also actuated so that tip 121 moves away from heat-generating structure 102 and toward top plate 110. FIG. 1D can thus be considered to depict the end of an up stroke of cooling element 120. Because of the motion of cooling element 120, gap 142 has decreased in size and is shown as gap 142C. Gap 152 has increased in size and is shown as gap 152C. Thus, a higher pressure is present near gap 142C, while a lower pressure is present near gap 152C. The net motion of fluid through chamber 140/150 is indicated in FIGS. 1C and 1D by unlabeled arrows. However, the unlabeled arrows in FIGS. 1C and 1D are not intended to indicate the motion of fluid at a particular time. Thus, cooling system 100 is able to drive fluid from top chamber 140 to bottom chamber 150 without an undue amount of backflow of heated fluid from the jet channel entering bottom chamber 150. Moreover, cooling system 100 may operate such that fluid is drawn in through vent 112 and driven out through orifices 132 without cooling element 120 contacting top plate 110 or orifice plate 130. Thus, pressures are developed within chambers 140 and 150 that effectively open and close vent 112 (e.g., by pressures near gap 142/142B/142C) and orifices 132 (e.g. by pressures near gap 152/152B/152C) such that fluid is driven through cooling system 100 as described herein.

The motion between the positions shown in FIGS. 1C and 1D is repeated. Thus, cooling element 120 undergoes vibrational motion indicated in FIGS. 1A-1D, drawing fluid through vent 112 from the distal side of top plate 110 into top chamber 140; transferring fluid from top chamber 140 to bottom chamber 150; and pushing the fluid through orifices 132 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at frequencies from 15 kHz through 30 kHz. In some embodiments, cooling element 120 vibrates at a frequency/frequencies of at least 20 kHz and not more than 30 kHz. In some embodiments, cooling element vibrates at a frequency of at least 23 kHz and not more than 26 kHz. The structural resonant frequency of cooling element 120 may be within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 may move substantially normal (perpendicular) to the top surface of heat-generating structure 102. In some embodiments, the fluid motion may have a nonzero acute angle with respect to the normal to the top surface of heat-generating structure 102. In either case, the fluid may thin and/or form apertures in the boundary layer of fluid at heat-generating structure 102. As a result, transfer of heat from heat-generating structure 102 may be improved. The fluid travels along the surface of heat-generating structure 102. Thus, heat from heat-generating structure 102 may be extracted by the fluid. The fluid may exit the region between orifice plate 130 and heat-generating structure 102 at the edges of cooling system 100. Chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

FIGS. 1E-1F depict an embodiment of active MEMS cooling system 100 including centrally anchored cooling element 120 in which the cooling element is driven out-of-phase. More specifically, sections of cooling element 120 on opposite sides of anchor 160 (and thus on opposite sides of the central region of cooling element 120 that is supported by anchor 160) are driven to vibrate out-of-phase. In some embodiments, sections of cooling element 120 on opposite sides of anchor 160 are driven at or near one hundred and eighty degrees out-of-phase. Thus, one section of cooling element 120 vibrates toward top plate 110, while the other section of cooling element 120 vibrates toward orifice plate 130/heat-generating structure 102. Thus, one section of cooling element 120 may carry out an upstroke, while the other section performs a downstroke. Thus, fluid traveling at high speeds (e.g. speeds described with respect to in-phase operation) is alternately driven out of orifices 132 on opposing sides of anchor 160. Because fluid is driven through orifices 132 at high speeds, cooling system 100 may be viewed as a MEMs jet. The net movement of fluid is shown by unlabeled arrows in FIGS. 1E and 1F. However, the unlabeled arrows in FIGS. 1E and 1F are not intended to indicate the motion of fluid at a particular time. The motion between the positions shown in FIGS. 1E and 1F is repeated. Thus, cooling element 120 undergoes vibrational motion indicated in FIGS. 1A, 1E and 1F, alternately drawing fluid through vent 112 from the distal side of top plate 110 into top chamber 140 for each side of cooling element 120; transferring fluid from each side of top chamber 140 to the corresponding side of bottom chamber 150; and pushing the fluid through orifices 132 on each side of anchor 160 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at the frequencies described for in-phase vibration. The structural resonant frequency of cooling element 120 may be within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 for out-of-phase vibration may move in a manner analogous to that described above for in-phase operation. Similarly, chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

Although shown in the context of a uniform cooling element in FIGS. 1A-1F, cooling system 100 may utilize cooling elements having different shapes. FIG. 1G depicts an embodiment of engineered cooling element 120’ having a tailored geometry and usable in a cooling system such as cooling system 100. Cooling element 120’ includes an anchored region 122 and cantilevered arms 123. Anchored region 122 is supported (e.g. held in place) in cooling system 100 by anchor 160. Cantilevered arms 123 undergo vibrational motion in response to cooling element 120’ being actuated. Each cantilevered arm 123 includes step region 124, extension region 126 and outer region 128. In the embodiment shown in FIG. 1G, anchored region 122 is centrally located. Step region 124 extends outward from anchored region 122. Extension region 126 extends outward from step region 124. Outer region 128 extends outward from extension region 126. In other embodiments, anchored region 122 may be at one edge of the actuator and outer region 128 at the opposing edge. In such embodiments, the actuator is edge anchored.

Extension region 126 has a thickness (extension thickness) that is less than the thickness of step region 124 (step thickness) and less than the thickness of outer region 128 (outer thickness). Thus, extension region 126 may be viewed as recessed. Extension region 126 may also be seen as providing a larger bottom chamber 150. In some embodiments, the outer thickness of outer region 128 is the same as the step thickness of step region 124. In some embodiments, the outer thickness of outer region 128 is different from the step thickness of step region 124. In some embodiments, outer region 128 and step region 124 each have a thickness of at least three hundred twenty micrometers and not more than three hundred and sixty micrometers. In some embodiments, the outer thickness is at least fifty micrometers and not more than two hundred micrometers thicker than the extension thickness. Stated differently, the step (difference in step thickness and extension thickness) is at least fifty micrometers and not more than two hundred micrometers. In some embodiments, the outer step (difference in outer thickness and extension thickness) is at least fifty micrometers and not more than two hundred micrometers. Outer region 128 may have a width, q, of at least one hundred micrometers and not more than three hundred micrometers. Extension region 126 has a length, e, extending outward from the step region of at least 0.5 millimeter and not more than 1.5 millimeters in some embodiments. In some embodiments, outer region 128 has a higher mass per unit length in the direction from anchored region 122 than extension region 126. This difference in mass may be due to the larger size of outer region 128, a difference in density between portions of cooling element 120, and/or another mechanism.

Use of engineered cooling element 120’ may further improve efficiency of cooling system 100. Extension region 126 is thinner than step region 124 and outer region 128. This results in a cavity in the bottom of cooling element 120’ corresponding to extension region 126. The presence of this cavity aids in improving the efficiency of cooling system 100. Each cantilevered arm 123 vibrates towards top plate 110 in an upstroke and away from top plate 110 in a downstroke. When a cantilevered arm 123 moves toward top plate 110, higher pressure fluid in top chamber 140 resists the motion of cantilevered arm 123. Furthermore, suction in bottom chamber 150 also resists the upward motion of cantilevered arm 123 during the upstroke. In the downstroke of cantilevered arm 123, increased pressure in the bottom chamber 150 and suction in top chamber 140 resist the downward motion of cantilevered arm 123. However, the presence of the cavity in cantilevered arm 123 corresponding to extension region 126 mitigates the suction in bottom chamber 150 during an upstroke. The cavity also reduces the increase in pressure in bottom chamber 150 during a downstroke. Because the suction and pressure increase are reduced in magnitude, cantilevered arms 123 may more readily move through the fluid. This may be achieved while substantially maintaining a higher pressure in top chamber 140, which drives the fluid flow through cooling system 100. Moreover, the presence of outer region 128 may improve the ability of cantilevered arm 123 to move through the fluid being driven through cooling system 100. Outer region 128 has a higher mass per unit length and thus a higher momentum. Consequently, outer region 128 may improve the ability of cantilevered arms 123 to move through the fluid being driven through cooling system 100. The magnitude of the deflection of cantilevered arm 123 may also be increased. These benefits may be achieved while maintaining the stiffness of cantilevered arms 123 through the use of thicker step region 124. Further, the larger thickness of outer region 128 may aid in pinching off flow at the bottom of a downstroke. Thus, the ability of cooling element 120’ to provide a valve preventing backflow through orifices 132 may be improved. Thus, performance of cooling system 100 employing cooling element 120’ may be improved.

Further, cooling elements used in cooling system 100 may have different structures and/or be mounted differently than depicted in FIGS. 1A-1G. In some embodiments, the cooling element may have rounded corners and/or rounded ends but still be anchored along a central axis such that cantilevered arms vibrate. The cooling element may be anchored only at its central region such that the regions surrounding the anchor vibrate in a manner analogous to a jellyfish or the opening/closing of an umbrella. In some such embodiments, the cooling element may be circular or elliptical in shape. In some embodiments, the anchor may include apertures through which fluid may flow. Such an anchor may be utilized for the cooling element being anchored at its top (e.g. to the top plate). Although not indicated in FIGS. 1A-1G, the piezoelectric material utilized in driving the cooling element may have various locations and/or configurations. For example, the piezoelectric material may be embedded in the cooling element, affixed to one side of the cooling element (or cantilevered arm(s)), may occupy some or all of the cantilevered arms, and/or may have a location that is close to or distal from the anchored region. In some embodiments, cooling elements that are not centrally anchored may be used. For example, a pair of cooling elements that have offset apertures, that are anchored at their ends (or all edges), and which vibrate out of phase may be used. Thus, various additional configurations of cooling element 120 and/or 120’, anchor 160, and/or other portions of cooling system 100 may be used.

Using the cooling system 100 actuated for in-phase vibration or out-of-phase vibration of cooling element 120 and/or 120’, fluid drawn in through vent 112 and driven through orifices 132 may efficiently dissipate heat from heat-generating structure 102. Stated differently, heat transfer between heat-generating structure 102 and the moving fluid is improved. Because the heat-generating structure is more efficiently cooled, the corresponding integrated circuit may be run at higher speed and/or power for longer times. For example, if the heat-generating structure corresponds to a high-speed processor, such a processor may be run for longer times before throttling. Thus, performance of a device utilizing cooling system 100 may be improved. Further, cooling system 100 may be a MEMS device. Consequently, cooling systems 100 may be suitable for use in smaller and/or mobile devices, such as smart phones, other mobile phones, virtual reality headsets, tablets, two-in-one computers, wearables and handheld games, in which limited space is available. Performance of such devices may thus be improved. Because cooling element 120/120’ may be vibrated at frequencies of 15 kHz or more, users may not hear any noise associated with actuation of cooling elements. If driven at or near structural and/or acoustic resonant frequencies, the power used in operating cooling systems may be significantly reduced. Cooling element 120/120’ may not physically contact top plate 110 or orifice plate 130 during vibration in normal operation. Thus, resonance of cooling element 120/120’ may be more readily maintained. Issues related to moving away from resonance may be mitigated or avoided through the use of pressure differentials and fluid flow as discussed above. The benefits of improved, quiet cooling may be achieved with limited additional power. Further, out-of-phase vibration of cooling element 120/120’ allows the position of the center of mass of cooling element 120/120’ to remain more stable. Although a torque is exerted on cooling element 120/120’, the force due to the motion of the center of mass is reduced or eliminated. As a result, vibrations due to the motion of cooling element 120/120’ may be reduced. Moreover, efficiency of cooling system 100 may be improved through the use of out-of-phase vibrational motion for the two sides of cooling element 120/120’. Consequently, performance of devices incorporating the cooling system 100 may be improved. Further, cooling system 100 may be usable in other applications (e.g. with or without heat-generating structure 102) in which high fluid flows and/or velocities are desired.

In addition, cooling system 100 may have a high back pressure. Back pressure is a measure of the resistance to a fluid flow driven through a system. The back pressure may be considered to be the pressure at which flow through the system goes to zero. Stated differently, the back pressure may be the pressure at which the system can no longer drive fluid flow. Cooling system 100 may have a high back pressure. For example, in some embodiments, the back pressure of cooling system 100 may be on the order of 2 kPa. Depending upon the geometry and fluid used, higher back pressures may be possible. For example, the back pressure of cooling system 100 may be on the order of 6-11 kPa in some embodiments. In some embodiments, the back pressure of cooling system 100 may be 8-10 kPa. As such, system 100 may be capable of driving fluid, and cooling heat-generating structure 102, even at higher pressures (e.g., 2 kPa, 6 kPa, or up to 8-10 kPa).

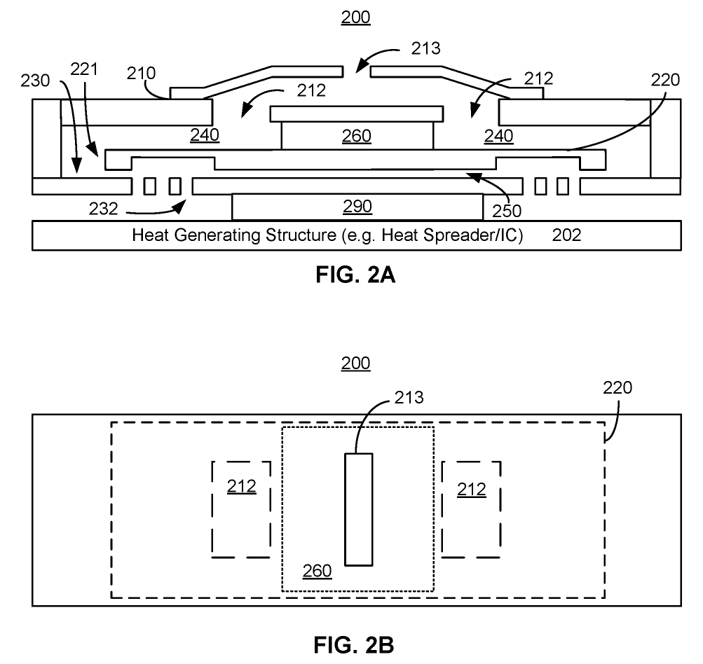

FIGS. 2A-2B depict an embodiment of active MEMS cooling system 200 including a top centrally anchored cooling element. FIG. 2A depicts a side view of cooling system 200 in a neutral position. FIG. 2B depicts a top view of cooling system 200. FIGS. 2A-2B are not to scale. For simplicity, only portions of cooling system 200 are shown. Referring to FIGS. 2A-2B, cooling system 200 is analogous to cooling system 100. Consequently, analogous components have similar labels. For example, cooling system 200 is used in conjunction with heat-generating structure 202, which is analogous to heat-generating structure 102.

Cooling system 200 includes top plate 210 having vents 212, cooling element 220 having tip 221, orifice plate 230 including orifices 232, top chamber 240 having a gap, bottom chamber 250 having a gap, flow chamber 240/250, and anchor (i.e. support structure) 260 that are analogous to top plate 110 having vent 112, cooling element 120 having tip 121, orifice plate 130 including orifices 132, top chamber 140 having gap 142, bottom chamber 150 having gap 152, flow chamber 140/150, and anchor (i.e. support structure) 160, respectively. Also shown is pedestal 290 analogous to pedestal 190. Thus, cooling element 220 is centrally supported by anchor 260 such that at least a portion of the perimeter of cooling element 220 is free to vibrate. In some embodiments, anchor 260 extends along the axis of cooling element 220. In other embodiments, anchor 260 is only near the center portion of cooling element 220. Although not explicitly labeled in FIGS. 2A and 2B, cooling element 220 includes an anchored region and cantilevered arms including step region, extension region, and outer regions analogous to anchored region 122, cantilevered arms 123, step region 124, extension region 126, and outer region 128 of cooling element 120’. In some embodiments, cantilevered arms of cooling element 220 are driven in-phase. In some embodiments, cantilevered arms of cooling element 220 are driven out-of-phase. In some embodiments, a simple cooling element, such as cooling element 120, may be used. Further, although cavities analogous to cavities 134 and 135 are not depicted in cooling system 200, such cavities may be present.

Anchor 260 supports cooling element 220 from above. Thus, cooling element 220 is suspended from anchor 260. Anchor 260 is suspended from top plate 210. Top plate 210 includes vent 213. Vents 212 on the sides of anchor 260 provide a path for fluid to flow into sides of chamber 240.

As discussed above with respect to cooling system 100, cooling element 220 may be driven to vibrate at or near the structural resonant frequency of cooling element 220. Further, the structural resonant frequency of cooling element 220 may be configured to align with the acoustic resonance of chamber 240/250. The structural and acoustic resonant frequencies are generally chosen to be in the ultrasonic range. For example, the vibrational motion of cooling element 220 may be at the frequencies described with respect to cooling system 100. Consequently, efficiency and flow rate may be enhanced. However, other frequencies may be used.

Cooling system 200 operates in an analogous manner to cooling system 100. Cooling system 200 thus shares the benefits of cooling system 100. Thus, performance of a device employing cooling system 200 may be improved. In addition, suspending cooling element 220 from anchor 260 may further enhance performance. In particular, vibrations in cooling system 200 that may affect other cooling cells (not shown) may be reduced. For example, less vibration may be induced in top plate 210 due to the motion of cooling element 220. Consequently, cross talk between cooling system 200 and other cooling systems (e.g. other cells) or other portions of the device incorporating cooling system 200 may be reduced. Thus, performance may be further enhanced.

FIGS. 3A-3E depict an embodiment of active MEMS cooling system 300 including multiple cooling cells configured as a module termed a tile, or array. FIG. 3A depicts a perspective view with spout 380 removed. FIG. 3B depicts active MEMS cooling system 300, or tile 300, with cover 306 and spout 380. FIG. 3C depicts a side view of a portion of cooling system 300. FIGS. 3D-3E depict side/cross-sectional views of cooling system 300. FIGS. 3A-3E are not to scale. Cooling system 300 includes four cooling cells 301A, 301B, 301C and 301D (collectively or generically 301), which are analogous to one or more of cooling systems described herein. More specifically, cooling cells 301 are analogous to cooling system 100 and/or 200. Tile 300 thus includes four cooling cells 301 (i.e. four MEMS jets). Although four cooling cells 301 in a 2x2 configuration are shown, in some embodiments another number and/or another configuration of cooling cells 301 might be employed. In the embodiment shown, cooling cells 301 include shared top plate 310 having apertures 312, cooling elements 320, shared orifice plate 330 including orifices 332, top chambers 340, bottom chambers 350, anchors (support structures) 360, and pedestals 390 that are analogous to top plate 110 having apertures 112, cooling element 120, orifice plate 130 having orifices 132, top chamber 140, bottom chamber 150, anchor 160, and pedestal 190. In some embodiments, cooling cells 301 may be fabricated together and separated, for example by cutting through top plate 310, side walls between cooling cells 301, and orifice plate 330. Thus, although described in the context of a shared top plate 310 and shared orifice plate 330, after fabrication cooling cells 301 may be separated. In some embodiments, tabs (not shown) and/or other structures such as anchors 360 may connect cooling cells 301.

Although not shown, cooling cells 301 may have cavities analogous to cavities 114, 134, and/or 135. Further, tile 300 includes heat-generating structure (termed a heat spreader hereinafter) 302 (e.g. a heat sink, a heat spreader, and/or other structure) that also has sidewalls, or fencing, in the embodiment shown. Cover 306 having apertures therein is also shown. In some embodiments, a dust filter (not shown) may be provided for the apertures. In such embodiments, dust may be less likely to reach the interior of cooling system 300. In some embodiments, a water tight, air porous membrane may be provided for the apertures. Heat spreader 302, cover 306, and spout 380 may be part of an integrated tile 300 as shown or may be separate from tile 300 in other embodiments. Heat spreader 302 and cover plate 306 may direct fluid flow outside of cooling cells 301, provide mechanical stability, and/or provide protection. Electrical connection to cooling cells 301 is provided via flex connector 381 (not shown in FIGS. 3C-3E) which may house drive electronics 385. Cooling elements 320 are driven out-of-phase (i.e. in a manner analogous to a see-saw). Further, as can be seen in FIGS. 3D-3E cooling element 320 in one cell is driven out-of-phase with cooling element(s) 320 in adjacent cell(s). Cooling elements 320 in a column are driven out-of-phase. Thus, cooling element 320 in cell 301A is out-of-phase with cooling element 320 in cell 301C. Similarly, cooling element 320 in cell 301B is out-of-phase with cooling element 320 in cell 301D. By driving cooling elements 320 out-of-phase, vibrations in cooling system 300 may be reduced. Cooling elements 320 may be driven in another manner in some embodiments. For example, cooling elements 301A and 301C may be driven in-phase but out-of-phase with cooling element 301B and 301D.

Direct flow through cooling system 300 may be at least 0.3 cfm (e.g. on the order of 0.35 cfm) and entrained flow may be at least 0.5 cfm (e.g. 0.7 cfm or approximately twice the direct flow). Other airflows are possible. The entrained airflow achieved using cooling system 300 may be at least the same as the direct airflow. In some embodiments, the entrained airflow is at least 1.5 multiplied by the direct airflow through cooling system 300. In some embodiments, the entrained airflow may be twice the direct airflow through cooling system 300. Other ratios are possible. At such flows, the back pressure for cooling system 300 may be not more than 2 kPa-2.2 kPa. Further, cooling system 300 may have a top surface temperature that is significantly lower than the temperature of heat spreader 302 or the heat spreader (not shown) to which cooling system 300 is coupled.

Cooling system 300 may also include spout 380 having dissipation region 386 therein. Thus, cooling system 300 including top cover 306 and heat spreader 302 may have a total thickness not exceeding four millimeters. In some embodiments, the height of cooling system 300 does not exceed 3.5 millimeters. In some embodiments, the height of cooling system 300 does not exceed 3 millimeters. In some embodiments, cooling system 300 has a height of at least 2 millimeters. Spout 380 includes a housing having bottom 382 and top 384, entrance 381 and exit 386. Entrance 381 is fluidically coupled with orifices 332 (i.e. egresses from flow chamber 340/350). The direction of fluid flow from flow chamber 340/350 may be seen by the unlabeled arrows in FIG. 3C. Spout 380 operates to smooth pulsations in the pressure waves generated by cooling elements 320. Because cooling elements 320 vibrate, the flow of fluid pulsates. Thus, the pressure of the fluid also pulsates between higher and lower pressures. Flow may also exit orifices 332 and travel through the jet channel in pulses. The pressure within flow chamber 340/350 and the jet channel is higher than the pressure of the ambient region. The fluid exits the jet channel and enters spout 380 at entrance 381. The fluid travels through dissipation region 386 and to exit 388. The pulsating pressure in the fluid is dissipated in dissipation region 384. Stated differently, the pulsations in pressure may be attenuated such that the pressure equilibrates and approaches (or reaches) the ambient pressure of the ambient region outside of system 300. In some embodiments, therefore, the pressure of the fluid at exit 388 of spout 380 matches or substantially the boundary conditions for the pressure of the ambient. In some embodiments of cooling system 300, spout 380 may be omitted. Also shown in FIG. 3C is optional dust guard 313. Dust guard 313 may be a MERV 14 or other analogous filter used to reduce or eliminate small particles from entering cooling system 300. Further, although cavities analogous to cavities 134 are not depicted in cooling system 300, such cavities may be present.

Cooling cells 301 of cooling system 300 function in an analogous manner to cooling system(s) 100, 200, and/or an analogous cooling system. Consequently, the benefits described herein may be shared by cooling system 300. Because cooling elements in nearby cells are driven out-of-phase, vibrations in cooling system 300 may be reduced. Because multiple cooling cells 301 are used, cooling system 300 may enjoy enhanced cooling capabilities. Further, multiples of individual cooling cells 301 and/or cooling system 300 may be combined in various fashions to obtain the desired footprint of cooling cells.

The MEMs cooling systems, also termed fluid transfer systems, described herein utilize vibration of an actuator, or cooling element, to drive a fluid such as air. For example, systems 100 and 200 and cooling cell 301 utilize actuators 120, 220, and 320, respectively. Thus, systems 100, 200, and 301 may be considered vibrational air (and/or other fluid) transfer devices. Vibrational air transfer devices 100, 200, and 301 may be desired to operate for long periods of time (e.g. a very large number cycles of vibration of actuators 120, 220, and 320) without weakening of joints that may cause failure. For example, the joint between pedestals 190, 290, and 390 and vibrational air transfer devices 100, 200, and 301 are desired to remain sufficiently robust that failure takes a significant amount of time. Similarly, vibrational air transfer devices 100, 200, and 301 may be desired to withstand falls and/or other sharp impacts. Cooling systems 400, 500, 600, 700, 800, 900, 1000, 1100, 1200, 1300, and/or 1400 may have such improved robustness while maintaining or not unduly sacrificing performance.

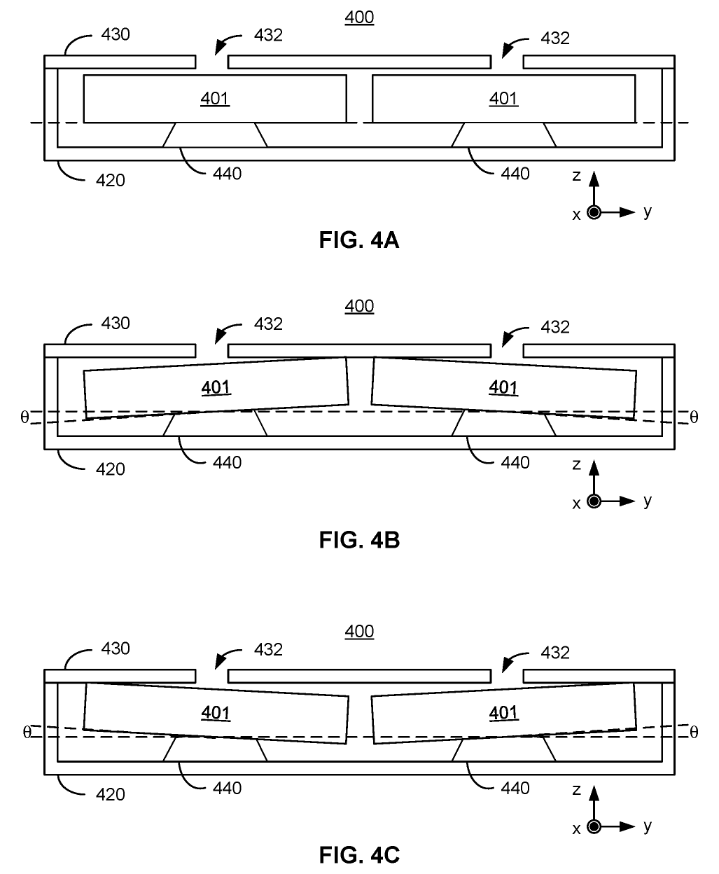

FIGS. 4A-4C depict cross-sectional views of an embodiment of active MEMS cooling system 400 including vibrational air transfer device 401 thermally and mechanically coupled to heat spreader 420. For clarity, FIGS. 4A-4C are not to scale. In addition, not all portions of system 400 may be shown. Although two vibrational air transfer devices 401 are shown, another number may be present. Vibrational air transfer device 401 is analogous to systems 100 and 200 and cell 301. Thus, vibrational air transfer device 401 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 400 also includes heat spreader 420 and top plate 430 having apertures 432 therein. Heat spreader 420 may be analogous to heat spreader 102, 202, and/or 302. Top plate 430 may be analogous to top plate 306. Thus, system 400 may be analogous to system 300. Operation of vibrational air transfer devices 401 and system 400, as well as the dimensions, are analogous to those described herein.

System 400 also includes coupler 440 for each vibrational air transfer device 401. Although one coupler 440 that is centrally located for each vibrational air transfer device 401 is shown, another number having other location(s) may be used. Couplers 440 thermally and mechanically couple vibrational air transfer devices 401 to heat spreader 420. Because vibrational air transfer devices 401 are thermally coupled with heat spreader 420, heat may be transferred from heat spreader 420 to vibrational air transfer devices 401 via conduction. The fluid (e.g. air) driven by vibrational air transfer devices 401 may then carry the heat from vibrational air transfer devices 401 and heat spreader 420. Thus, cooling may be efficient.

Coupler 440 mechanically couples vibrational air transfer devices 401 such that some motion is allowed, while other motion is damped and/or restricted. Vibrational air transfer devices 401 define a plane when not energized (e.g., the actuator therein is not energized/driving fluid/vibrating). This is indicated by the dashed line in FIG. 4A. In FIG. 4A, vibrational air transfer devices 401 are quiescent (i.e., not energized and in a static configuration). The plane defined by the vibrational air transfer device may not be a perfect, mathematical plane. The plane may be irregularly shaped and have a topography. The mechanical coupling via couplers 440 allows tilting of vibrational air transfer devices 401 as shown in FIGS. 4B and 4C. The tilt with respect to the plane is indicated by angled dashed lines indicating an angle, q. Although tilting of vibrational air transfer devices 401 is shown in the opposite direction, in some embodiments, vibrational air transfer devices 401 tilt in the same direction. In some embodiments, q is not more than forty degrees. In some embodiments, q is not more than thirty degrees. In some embodiments, q is not more than twenty degrees. In addition, q is nonzero. In some embodiments, q is at least five degrees. In some embodiments, q is at least ten degrees. Other angles are possible in some embodiments.

The tilting of vibrational air transfer devices 401 may be driven by the oscillations of actuators within vibrational air transfer devices 401. Thus, vibrational air transfer devices 401 may tilt, or hinge, around an axis parallel to the central axis of the actuators shown in FIGS. 1A-1G, FIG. 2, and FIGS. 3C-3E. In the embodiment shown, this axis is parallel to the x axis. Thus, the cross-sectional view shown in FIGS. 4A-4C may be taken along a plane parallel to those for FIGS. 1A-1F, FIG. 2, and FIGS. 3D-3E. The plane of the view shown in FIGS. 4A-4C is also perpendicular to the plane shown in FIG. 3C.

Although couplers 440 allow tilting around an axis parallel to the x-axis, other motion may be damped, or restricted. Couplers 440 may restrict vibrational air transfer device 401 from tilting around at least one of a second axis at a first nonzero angle from the first axis or a third axis at a second nonzero angle from the axis. Vibrational air transfer device 401 may be allowed to tilt around a first axis, but a yaw (tilt around a second axis perpendicular to the first axis) and/or a pitch (tilt around a third axis perpendicular to the first and second axes) may be restricted. For example, couplers 440 may limit pitch and yaw with respect to the x-axis (rotation around the y-axis and rotation around the z-axis). Because vibrational air transfer devices 401 may tilt, the actuators therein are better able to drive fluid (e.g. air) through system 400. Thus, the ability of system 400 to transfer heat more effectively may be substantially maintained. Further, couplers 440 allow thermal connection via thermal conduction between heat spreader 420 and vibrational air transfer devices 401. Thus, again, the ability of vibrational air transfer devices 401 and system 400 to provide cooling and fluid transfer may be substantially maintained.

Couplers 440 may also allow vibrational air transfer devices 401 to be more robust. In particular, couplers 440 may allow system 400 and/or the connection between vibrational air transfer devices 401 and heat spreader 420 to withstand greater impacts/larger shocks. In some embodiments, the mechanical coupling (e.g. couplers 440) between heat spreader 420 and vibrational air transfer devices 401 allows for the system to withstand forces (e.g. shocks) of at least 200 g (g = earth’s gravity at or near the earth’s surface), at least 300 g, at least 400 g, at least 500 g, at least 600 g, at least 700 g, at least 800 g, at least 900 g, at least 1000 g, at least 1300 g, at least 1500 g, and/or at least 2000 g. In some embodiments, the mechanical coupling allows the heat spreader and the vibrational air transfer device to withstand forces (e.g. shocks/impacts) of not more than 500g, 1000 g, 2000 g, or 5000 g. For example, damage to couplers 440 due to such shocks may be reduced or eliminated. Consequently, vibrational air transfer devices 401 and system 400 may be made significantly more robust.

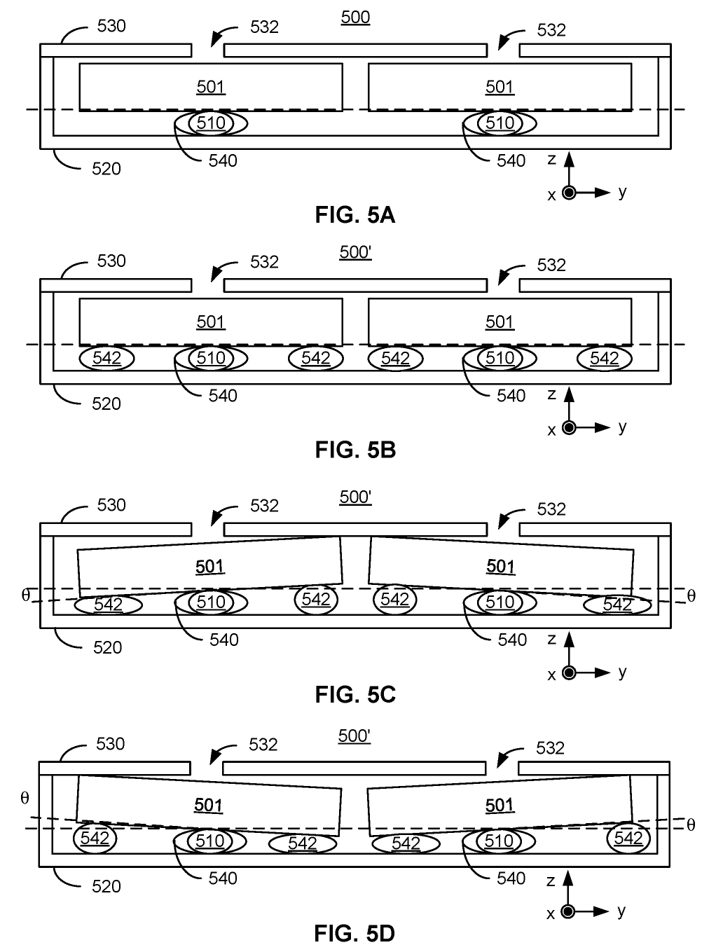

FIGS. 5A-5D depict cross-sectional views of embodiments of active MEMS cooling systems 500 and 500’ including vibrational air transfer devices 501 thermally and mechanically coupled to heat spreader 520. For clarity, FIGS. 5A-5D are not to scale. In addition, not all portions of systems 500 may be shown. Although two vibrational air transfer devices 501 are shown in each system 500 and 500’, another number may be present.

Vibrational air transfer device 501 is analogous to vibrational air transfer devices 401 and, therefore, systems 100 and 200 and cell 301. Thus, vibrational air transfer device 501 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. Systems 500 and 500’ each also includes heat spreader 520 and top plate 530 having apertures 532 therein. Heat spreader 520 may be analogous to heat spreader 102, 202, and/or 302. Top plate 530 may be analogous to top plate 306. Thus, system 500 may be analogous to system 300. Operation of vibrational air transfer devices 501 and system 500, as well as the dimensions, are analogous to those described herein.

Systems 500 and 500’ each includes pedestals 510 and fillets 540. Pedestals 510 and fillets 540 may combine to mechanically and thermally couple vibrational air transfer devices 501 to heat spreader 520 in a manner analogous to couplers 440. Pedestals 510 are analogous to pedestals 190, 290, and 390. In some embodiments, pedestals 510 are thermally conductive and provide mechanical support for vibrational air transfer devices 501. For example, pedestals 510 may be formed of thermally conductive epoxy and/or another thermally conductive silicone. However, pedestals 510 may not be as mechanically robust as the mechanical coupling provided by couplers 440. For example, pedestals 510 may be brittle. A crack may be initiated in such a pedestal 510 in response to system 500 being dropped in the absence of fillets 540. A crack in pedestals 510 may adversely affect the ability of vibrational air transfer device 501 to adequately function.

Fillets 540 improve the mechanical coupling between vibrational air transfer devices 501 and heat spreader 520. In some embodiments, fillets 540 surround the sides of pedestals 510. In some embodiments, fillets 540 do not surround pedestals 510. Fillets 540 may reduce or eliminate the formation of cracks in pedestals 510. Fillets 540 may partially support vibrational air transfer devices 501. Fillets 540 also damp translation or rotation around the axes parallel to the y axes and the z axis. Thus, fillets 540 may be made of a soft, tough material such as silicone. In some embodiments, fillets 540 may have a hardness of A20 through A60 on the Shore A hardness scale. In some embodiments, fillets 540 may reduce or prevent formation of a crack in pedestals 510. In some embodiments, fillets 542 of system 500’ are also present. Fillets 542 may be formed of the same material as fillets 540. Fillets 542 further restrict translation and/or other motion of vibrational air transfer devices 501.

Pedestals 510 in combination with fillets 540 and 542 mechanically couple vibrational air transfer devices 501 such that some tilting motion (e.g., around an axis parallel to the x-axis) is allowed, while other motion is damped and/or restricted. Vibrational air transfer devices 501 define a plane in a manner analogous to that described for vibrational air transfer device 400. This is indicated by the dashed lines in FIGS. 5A-5B, for which vibrational air transfer devices 501 are in a static configuration. The plane defined by the vibrational air transfer device 501 is analogous to the plane for vertical air transfer device 401.

The fillets 540 and 542 and pedestal 510 allow tilting of vibrational air transfer devices 501 as shown in FIGS. 5C and 5D. Although system 500’ is depicted in FIGS. 5C-5D, system 500 behaves in an analogous manner. The tilt with respect to the plane is indicated by angled dashed lines indicating an angle, q. Angle q for systems 500 and 500’ is analogous to the angle q for system 400. In some embodiments, q has the same range as for system 400. The tilting of vibrational air transfer devices 501 may be driven by the oscillations of actuators within vibrational air transfer devices 501. Thus, vibrational air transfer devices 501 may tilt, or hinge, around an axis parallel to the central axis of the actuators shown in FIGS. 1A-1G, FIG. 2, and FIGS. 3C-3D. In the embodiment shown, this axis is parallel to the x axis.

Although fillets 540 and 542 and pedestal 510 allow tilting around an axis parallel to the x-axis, other motion may be damped, or restricted. For example, translation in the x-, y-, and/or z-directions is restricted. Similarly, rotation around the y-axis and z-axis (i.e., pitch and yaw with respect to the x-axis) are similarly damped. Because vibrational air transfer devices 501 may tilt, the actuators therein are better able to drive fluid (e.g. air) through systems 500 and 500’. Thus, the ability of systems 500 and 500’ to transfer heat more effectively may be substantially maintained. Further, pedestals 510 allow thermal connection via thermal conduction between heat spreader 520 and vibrational air transfer devices 501. Thus, again, the ability of vibrational air transfer devices 501 and systems 500 and 500’ to provide cooling and fluid transfer may be substantially maintained.

Systems 500 and 500’ thus shares the benefits of system 400. Pedestals 510 and fillets 540 and 542 allow vibrational air transfer devices 501 to be more robust. In particular, fillets 540 and 542 may allow systems 500 and 500’ and/or the connection between vibrational air transfer devices 501 and heat spreader 520 to withstand greater impacts/larger shocks. In some embodiments, the mechanical coupling between heat spreader 520 and vibrational air transfer devices 501 allows for the system to withstand forces (e.g. shocks) in the ranges described for system 400. Tilting of vibrational air transfer devices 501 around an axis parallel to the x-axis is still allowed. This may improve the ability of vibrational air transfer devices 501 to drive flow. Consequently, vibrational air transfer devices 501 and systems 500 and 500’ may be made significantly more robust without significantly adversely affecting performance.

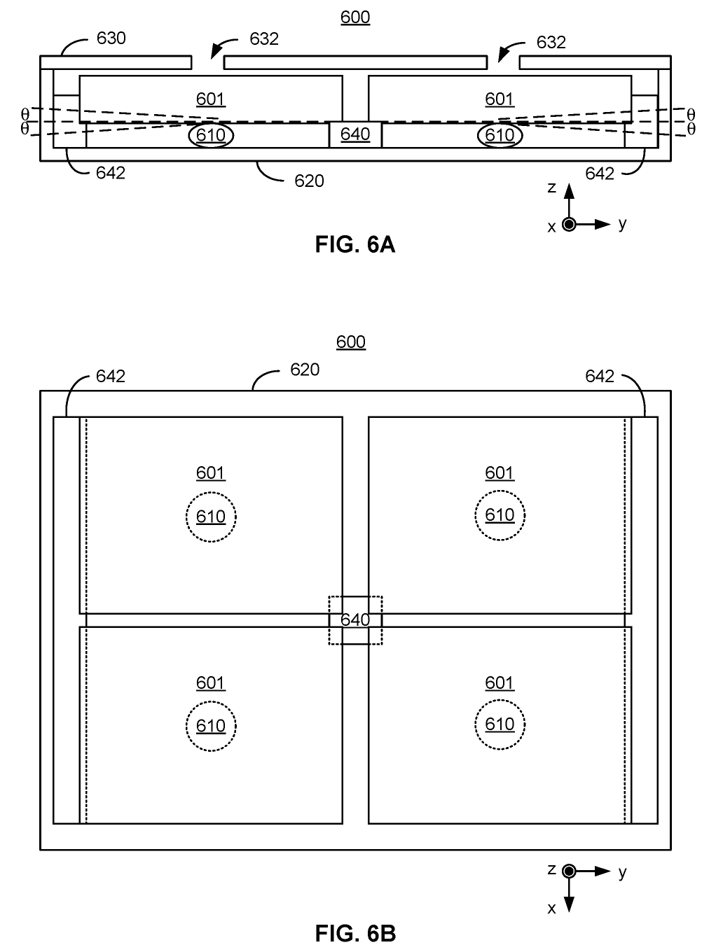

FIGS. 6A-6B depict cross-sectional and plan views of an embodiment of active MEMS cooling system 600 including vibrational air transfer devices 601 thermally and mechanically coupled to heat spreader 620. For clarity, FIGS. 6A-6B are not to scale. In addition, not all portions of system 600 may be shown. Although four vibrational air transfer devices 601 are shown, another number may be present. Vibrational air transfer device 601 is analogous to systems 100 and 200 and cell 301. Thus, vibrational air transfer device 601 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 600 also includes heat spreader 620 and top plate 630 having apertures 632 therein. Heat spreader 620 may be analogous to heat spreader 102, 202, and/or 302. Top plate 630 may be analogous to top plate 306. Thus, system 600 may be analogous to system 300. Operation of vibrational air transfer devices 601 and system 600, as well as the dimensions, are analogous to those described herein.

System 600 includes pedestals 610 and bumpers 640 and 642. Pedestals 610 and bumpers 640 and 642 may combine to mechanically and thermally couple vibrational air transfer devices 601 to heat spreader 620 in a manner analogous to couplers 440. Pedestals 610 are analogous to pedestals 190, 290, 390, and 510. In some embodiments, pedestals 610 are thermally conductive and provide mechanical support for vibrational air transfer devices 601. For example, pedestals 610 may be formed of thermally conductive epoxy and/or another thermally conductive silicone. However, pedestals 610 may not be as mechanically robust as the mechanical coupling provided by couplers 440.

Bumpers 640 and 642 improve the mechanical coupling between vibrational air transfer devices 601 and heat spreader 620. In some embodiments, bumpers 640 and 642 may partially support vibrational air transfer devices 601. Bumpers 640 and 642 also damp translation or rotation around the axes parallel to the y axes and the z axis. Thus, bumpers 640 and 642 may be made of a soft, tough material such as silicone. In some embodiments, bumpers 640 and 642 may have a hardness of A20 through A60 on the Shore A hardness scale. In some embodiments, bumpers 640 and 642 may also somewhat damp the tilting of vibrational air transfer devices 601.

Pedestals 610 in combination with bumpers 640 and 642 mechanically couple vibrational air transfer devices 601 such that some tilting motion (e.g., around an axis parallel to the x-axis) is allowed, while other motion is damped and/or restricted. Vibrational air transfer devices 601 define a plane in a manner analogous to that described for vibrational air transfer device 400. This is indicated by the horizontal dashed line in FIG. 6A, for which vibrational air transfer devices 601 are in a static configuration. The plane defined by the vibrational air transfer device 601 is analogous to the plane for vertical air transfer device 401.

Bumpers 640 and 642 and pedestal 610 allow tilting of vibrational air transfer devices 601. The tilt with respect to the plane is indicated in FIG. 6A by angled dashed lines indicating an angle, q. Angle q for system 600 is analogous to the angle q for systems 400 and/or 500. In some embodiments, q has the same range as for system 400. The tilting of vibrational air transfer devices 601 may be driven by the oscillations of actuators within vibrational air transfer devices 601. Thus, vibrational air transfer devices 601 may tilt, or hinge, around an axis parallel to the central axis of the actuators shown in FIGS. 1A-1G, FIG. 2, and FIGS. 3C-3D. In the embodiment shown, this axis is parallel to the x axis.

Although bumpers 640 and 642 and pedestal 610 allow tilting around an axis parallel to the x-axis, other motion may be damped, or restricted. For example, translation in the x-, y-, and/or z-directions is restricted. Similarly, rotation around the y-axis and z-axis (i.e., pitch and yaw with respect to the x-axis) are similarly damped. Because vibrational air transfer devices 601 may tilt, the actuators therein are better able to drive fluid (e.g. air) through system 600. Thus, the ability of system 600 to transfer heat more effectively may be substantially maintained. Further, pedestals 610 allow thermal connection via thermal conduction between heat spreader 620 and vibrational air transfer devices 601. Thus, again, the ability of vibrational air transfer devices 601 and system 600 to provide cooling and fluid transfer may be substantially maintained.

System 600 thus shares the benefits of system(s) 400 and/or 500. Pedestals 610 and bumpers 640 and 642 allow vibrational air transfer devices 601 to be more robust. In particular, bumpers 640 and 642 may allow system 600 and/or the connection between vibrational air transfer devices 601 and heat spreader 620 to withstand greater impacts/larger shocks. In some embodiments, the mechanical coupling between heat spreader 620 and vibrational air transfer devices 601 allows for the system to withstand forces (e.g. shocks) in the ranges described for system 400. Tilting of vibrational air transfer devices 601 around an axis parallel to the x-axis is still allowed, though may be somewhat damped. This may only somewhat the ability of vibrational air transfer devices 601 to drive flow. Consequently, vibrational air transfer devices 601 and system 600 may be made significantly more robust without significantly adversely affecting performance.

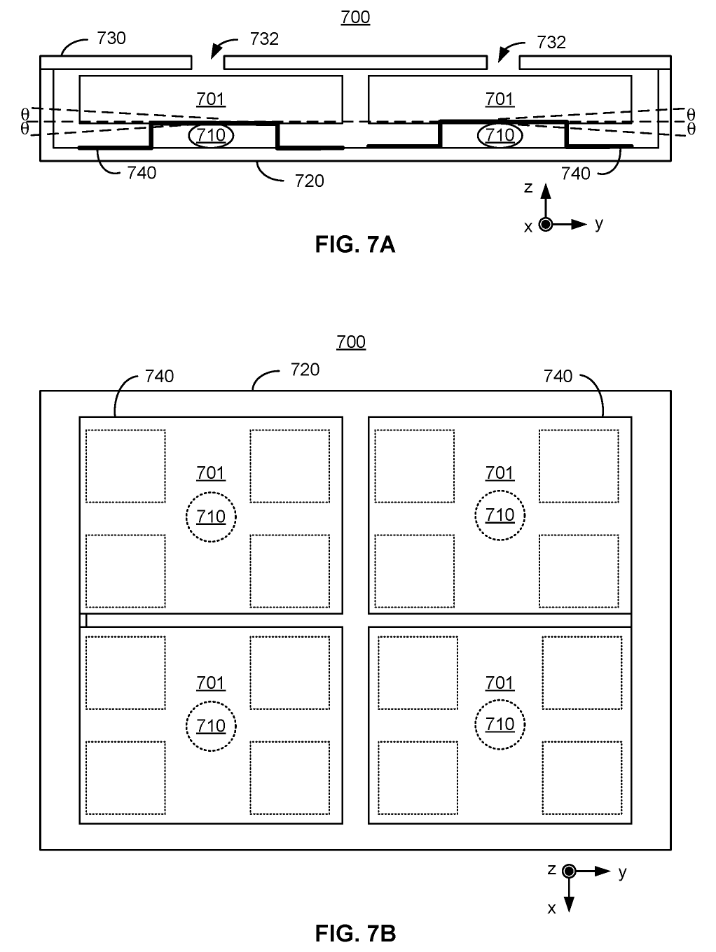

FIGS. 7A-7B depict cross-sectional and plan views of an embodiment of active MEMS cooling system 700 including vibrational air transfer devices 701 thermally and mechanically coupled to heat spreader 720. For clarity, FIGS. 7A-7B are not to scale. In addition, not all portions of system 700 may be shown. Although two vibrational air transfer devices 701 are shown, another number may be present. Vibrational air transfer device 701 is analogous to systems 100 and 200 and cell 301. Thus, vibrational air transfer device 701 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 700 also includes heat spreader 720 and top plate 730 having apertures 732 therein. Heat spreader 720 may be analogous to heat spreader 102, 202, and/or 302. Top plate 730 may be analogous to top plate 306. Thus, system 700 may be analogous to system 300. Operation of vibrational air transfer devices 701 and system 700, as well as the dimensions, are analogous to those described herein.

System 700 includes pedestals 710 and springs 740. Pedestals 710 and springs 740 may combine to mechanically and thermally couple vibrational air transfer devices 701 to heat spreader 720 in a manner analogous to couplers 440. Pedestals 710 are analogous to pedestals 190, 290, 390, 510, and 610. In some embodiments, pedestals 710 are thermally conductive and provide mechanical support for vibrational air transfer devices 701. For example, pedestals 710 may be formed of thermally conductive epoxy and/or another thermally conductive silicone. However, pedestals 710 may not be as mechanically robust as the mechanical coupling provided by couplers 440.

Springs 740 improve the mechanical coupling between vibrational air transfer devices 701 and heat spreader 720. In some embodiments, springs 740 may at least partially support vibrational air transfer devices 701. Springs 740 also damp translation or rotation around the axes parallel to the y axes and the z axis, while allowing tilting around an axis parallel to the x axis. Thus, springs 740 may be made of a flexible material such as stainless steel or copper. In some embodiments, therefore, springs 740 may also provide thermal coupling between vibrational air transfer device 701 and heat spreader 720 via thermal conduction. In some embodiments, springs 740 may sufficiently support the load from vibrational air transfer devices 701 while allowing tilting of vibrational air transfer devices that pedestals 710 may be omitted. Further, springs 740 may be more robust than pedestals 710.

Pedestals 710 in combination with springs 740 mechanically couple vibrational air transfer devices 701 such that some tilting motion (e.g., around an axis parallel to the x-axis) is allowed, while other motion is damped and/or restricted. Vibrational air transfer devices 701 define a plane in a manner analogous to that described for vibrational air transfer device 400. This is indicated by the horizontal dashed line in FIG. 7A, for which vibrational air transfer devices 701 are in a static configuration. The plane defined by the vibrational air transfer device 701 is analogous to the plane for vertical air transfer device 401.

Springs 740 and pedestal 710 allow tilting of vibrational air transfer devices 701. The tilt with respect to the plane is indicated in FIG. 7A by angled dashed lines indicating an angle, q. Angle q for system 700 is analogous to the angle q for systems 400, 500, and/or 600. In some embodiments, q has the same range as for system 400. The tilting of vibrational air transfer devices 701 may be driven by the oscillations of actuators within vibrational air transfer devices 701. Thus, vibrational air transfer devices 701 may tilt, or hinge, around an axis parallel to the central axis of the actuators shown in FIGS. 1A-1G, FIG. 2, and FIGS. 3C-3D. In the embodiment shown, this axis is parallel to the x axis.

Although springs 740 and pedestal 710 allow tilting around an axis parallel to the x-axis, other motion may be damped, or restricted. For example, translation in the x-, y-, and/or z-directions is restricted. Similarly, rotation around the y-axis and z-axis (i.e., pitch and yaw with respect to the x-axis) are similarly damped. Because vibrational air transfer devices 701 may tilt, the actuators therein are better able to drive fluid (e.g. air) through system 700. Thus, the ability of system 700 to transfer heat more effectively may be substantially maintained. Further, pedestals 710 and springs 740 allow thermal connection via thermal conduction between heat spreader 720 and vibrational air transfer devices 701. Thus, again, the ability of vibrational air transfer devices 701 and system 700 to provide cooling and fluid transfer may be substantially maintained.

System 700 thus shares the benefits of system(s) 400, 500, and/or 600. Pedestals 710 and springs 740 allow vibrational air transfer devices 701 to be more robust. In particular, springs 740 may allow system 700 and/or the connection between vibrational air transfer devices 701 and heat spreader 720 to withstand greater impacts/larger shocks. In some embodiments, the mechanical coupling between heat spreader 720 and vibrational air transfer devices 701 allows for the system to withstand forces (e.g. shocks) in the ranges described for system 400. This may be because springs 740 support at least a portion of the load from vibrational air transfer devices 701 and are more robust than pedestal 710. Thus, impacts or other shocks to system 700 may be largely or completely absorbed by springs 740 instead of pedestal 710. Tilting of vibrational air transfer devices 701 around an axis parallel to the x-axis is still allowed. Consequently, vibrational air transfer devices 701 and system 700 may be made significantly more robust without significantly adversely affecting performance.

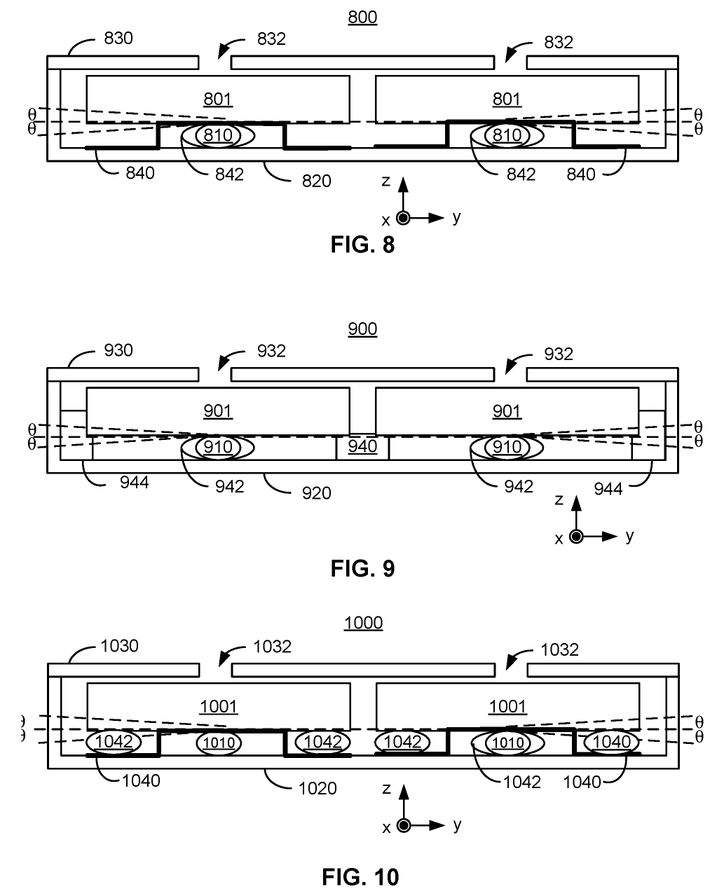

FIG. 8 depicts an embodiment of active MEMS cooling system 800 including vibrational air transfer devices 801 thermally and mechanically coupled to heat spreader 820. For clarity, FIG. 8 is not to scale. In addition, not all portions of system 800 may be shown. Although two vibrational air transfer devices 801 are shown, another number may be present. Vibrational air transfer device 801 is analogous to systems 100 and 200 and cell 301. Thus, vibrational air transfer device 801 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 800 also includes heat spreader 820 and top plate 830 having apertures 832 therein. Heat spreader 820 may be analogous to heat spreader 102, 202, and/or 302. Top plate 830 may be analogous to top plate 306. Thus, system 800 may be analogous to system 300. Operation of vibrational air transfer devices 801 and system 800, as well as the dimensions, are analogous to those described herein.

System 800 includes pedestals 810, springs 840, and fillets 842. Pedestals 810, springs 840, and fillets 842 may combine to mechanically and thermally couple vibrational air transfer devices 801 to heat spreader 820 in a manner analogous to couplers 440. Pedestals 810 are analogous to pedestals 190, 290, 390, 510, 610 and 710. In some embodiments, pedestals 810 are thermally conductive and provide mechanical support for vibrational air transfer devices 801. For example, pedestals 810 may be formed of thermally conductive epoxy and/or another thermally conductive silicone. However, pedestals 810 may not be as mechanically robust as the mechanical coupling provided by couplers 440.

Springs 840 and fillets 842 are analogous to springs 740 and fillets 540. System 800 may be viewed as a combination of systems 500 and 700. Springs 840 and fillets 842 may improve the mechanical coupling between vibrational air transfer devices 801 and heat spreader 820. In some embodiments, springs 840 and fillets 842 may at least partially support vibrational air transfer devices 801. Springs 840 and fillets 842 also damp translation or rotation around the axes parallel to the y axes and the z axis, while allowing tilting around an axis parallel to the x axis. Springs 840 may also provide thermal coupling between vibrational air transfer device 801 and heat spreader 820 via thermal conduction.

System 800 thus shares the benefits of system(s) 400, 500, 600, and/or 700. Pedestals 810, springs 840 and fillets 842 allow vibrational air transfer devices 801 to be more robust. In particular, springs 840 and fillets 842 may allow system 800 and/or the connection between vibrational air transfer devices 801 and heat spreader 820 to withstand greater impacts/larger shocks. In some embodiments, the mechanical coupling between heat spreader 820 and vibrational air transfer devices 801 allows for the system to withstand forces (e.g. shocks) in the ranges described for system 400. This may be because springs 840 support at least a portion of the load from vibrational air transfer devices 801 and are more robust than pedestal 810. Thus, impacts or other shocks to system 800 may be largely or completely absorbed by springs 840 instead of pedestal 810. Tilting of vibrational air transfer devices 801 around an axis parallel to the x-axis is still allowed. Consequently, vibrational air transfer devices 801 and system 800 may be made significantly more robust without significantly adversely affecting performance.

FIG. 9 depicts an embodiment of active MEMS cooling system 900 including vibrational air transfer devices 901 thermally and mechanically coupled to heat spreader 920. For clarity, FIG. 9 is not to scale. In addition, not all portions of system 900 may be shown. Although two vibrational air transfer devices 901 are shown, another number may be present. Vibrational air transfer device 901 is analogous to systems 100 and 200 and cell 301. Thus, vibrational air transfer device 901 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 900 also includes heat spreader 920 and top plate 930 having apertures 932 therein. Heat spreader 920 may be analogous to heat spreader 102, 202, and/or 302. Top plate 930 may be analogous to top plate 306. Thus, system 900 may be analogous to system 300. Operation of vibrational air transfer devices 901 and system 900, as well as the dimensions, are analogous to those described herein.

System 900 includes pedestals 910, bumpers 940 and 944, and fillets 942. Pedestals 910, bumpers 940 and 944, and fillets 942 may combine to mechanically and thermally couple vibrational air transfer devices 901 to heat spreader 920 in a manner analogous to couplers 440. Pedestals 910 are analogous to pedestals 190, 290, 390, 510, 610, 710, and 810. In some embodiments, pedestals 910 are thermally conductive and provide mechanical support for vibrational air transfer devices 901. For example, pedestals 910 may be formed of thermally conductive epoxy and/or another thermally conductive silicone. However, pedestals 910 may not be as mechanically robust as the mechanical coupling provided by couplers 440.

Bumpers 942 and 944 and fillets 942 are analogous to bumpers 640 and 642 and fillets 540. System 900 may be viewed as a combination of systems 500 and 600. Bumpers 940 and 942 and fillets 942 may improve the mechanical coupling between vibrational air transfer devices 901 and heat spreader 920. In some embodiments, bumpers 940 and 944, and fillets 942 may at least partially support vibrational air transfer devices 901. Springs 940 and fillets 942 also damp translation or rotation around the axes parallel to the y axes and the z axis, while allowing tilting around an axis parallel to the x axis.

System 900 thus shares the benefits of system(s) 400, 500, 600, 700, and/or 800. Pedestals 910, bumpers 940 and 944, and fillets 942 allow vibrational air transfer devices 901 to be more robust. In particular, bumpers 940 and 944, and fillets 942 may allow system 900 and/or the connection between vibrational air transfer devices 901 and heat spreader 920 to withstand greater impacts/larger shocks. In some embodiments, the mechanical coupling between heat spreader 920 and vibrational air transfer devices 901 allows for the system to withstand forces (e.g. shocks) in the ranges described for system 400. Tilting of vibrational air transfer devices 901 around an axis parallel to the x-axis is still allowed. Consequently, vibrational air transfer devices 901 and system 900 may be made significantly more robust without significantly adversely affecting performance.

FIG. 10 depicts an embodiment of active MEMS cooling system 1000 including vibrational air transfer devices 1001 thermally and mechanically coupled to heat spreader 1020. For clarity, FIG. 10 is not to scale. In addition, not all portions of system 1000 may be shown. Although two vibrational air transfer devices 1001 are shown, another number may be present. Vibrational air transfer device 1001 is analogous to systems 100 and 200 and cell 301. Thus, vibrational air transfer device 1001 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 1000 also includes heat spreader 1020 and top plate 1030 having apertures 1032 therein. Heat spreader 1020 may be analogous to heat spreader 102, 202, and/or 302. Top plate 1030 may be analogous to top plate 306. Thus, system 1000 may be analogous to system 300. Operation of vibrational air transfer devices 1001 and system 1000, as well as the dimensions, are analogous to those described herein.

System 1000 includes pedestals 1010, springs 1040, and fillets 1042. Pedestals 1010, springs 1040, and fillets 1042 may combine to mechanically and thermally couple vibrational air transfer devices 1001 to heat spreader 1020 in a manner analogous to couplers 440. Pedestals 1010 are analogous to pedestals 190, 290, 390, 510, 610, 710, 810, and 910. In some embodiments, pedestals 1010 are thermally conductive and provide mechanical support for vibrational air transfer devices 1001. For example, pedestals 1010 may be formed of thermally conductive epoxy and/or another thermally conductive silicone. However, pedestals 1010 may not be as mechanically robust as the mechanical coupling provided by couplers 440.

Springs 1040 and fillets 1042 are analogous to springs 740 and fillets 542. System 1000 may be viewed as a combination of systems 500’ and 700. Springs 1040 and fillets 1042 may improve the mechanical coupling between vibrational air transfer devices 1001 and heat spreader 1020. In some embodiments, springs 1040 and fillets 1042 may at least partially support vibrational air transfer devices 1001. Springs 1040 and fillets 1042 also damp translation or rotation around the axes parallel to the y axes and the z axis, while allowing tilting around an axis parallel to the x axis. Springs 1040 may also provide thermal coupling between vibrational air transfer device 1001 and heat spreader 1020 via thermal conduction.

System 1000 thus shares the benefits of system(s) 400, 500, 600, 700, 800, and/or 900. Pedestals 1010, springs 1040 and fillets 1042 allow vibrational air transfer devices 1001 to be more robust. In particular, springs 1040 and fillets 1042 may allow system 1000 and/or the connection between vibrational air transfer devices 1001 and heat spreader 1020 to withstand greater impacts/larger shocks. In some embodiments, the mechanical coupling between heat spreader 1020 and vibrational air transfer devices 1001 allows the system to withstand forces (e.g. shocks) in the ranges described for system 400. Tilting of vibrational air transfer devices 1001 around an axis parallel to the x-axis is still allowed. Consequently, vibrational air transfer devices 1001 and system 1000 may be made significantly more robust without significantly adversely affecting performance.

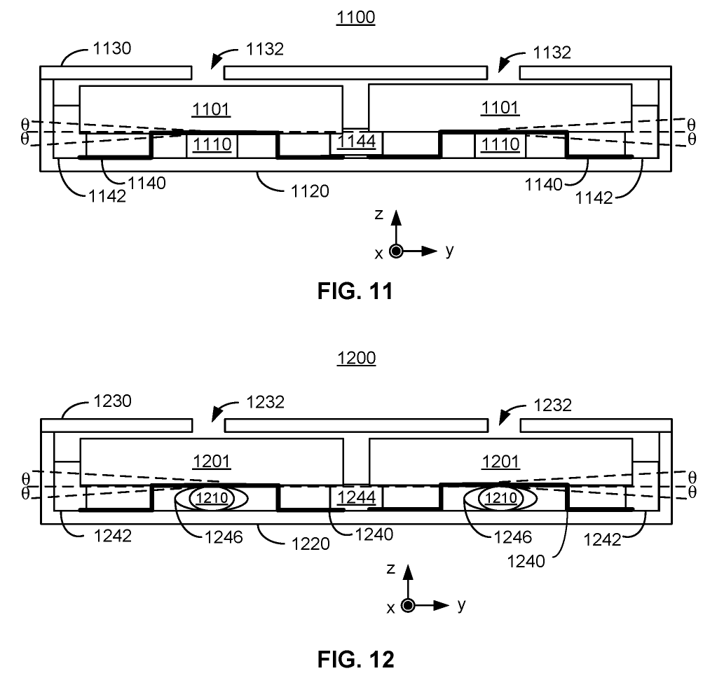

FIG. 11 depicts an embodiment of active MEMS cooling system 1100 including vibrational air transfer devices 1101 thermally and mechanically coupled to heat spreader 1120. For clarity, FIG. 11 is not to scale. In addition, not all portions of system 1100 may be shown. Although two vibrational air transfer devices 1101 are shown, another number may be present. Vibrational air transfer device 1101 is analogous to systems 100 and 200 and cell 301. Thus, vibrational air transfer device 1101 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 1100 also includes heat spreader 1120 and top plate 1130 having apertures 1132 therein. Heat spreader 1120 may be analogous to heat spreader 112, 202, and/or 302. Top plate 1130 may be analogous to top plate 306. Thus, system 1100 may be analogous to system 300. Operation of vibrational air transfer devices 1101 and system 1100, as well as the dimensions, are analogous to those described herein.

System 1100 includes pedestals 1110, springs 1140, and bumpers 1142 and 1144. Pedestals 1110, springs 1140, and bumpers 1142 and 1144 may combine to mechanically and thermally couple vibrational air transfer devices 1101 to heat spreader 1120 in a manner analogous to couplers 440. Pedestals 1110 are analogous to pedestals 190, 290, 390, 510, 610, 710, 810, 910, and 1010. In some embodiments, pedestals 1110 are thermally conductive and provide mechanical support for vibrational air transfer devices 1101. For example, pedestals 1110 may be formed of thermally conductive epoxy and/or another thermally conductive silicone. However, pedestals 1110 may not be as mechanically robust as the mechanical coupling provided by couplers 440.

Springs 1140 and bumpers 1142 and 1144 are analogous to springs 740 and bumpers 640 and 642. System 1100 may be viewed as a combination of systems 600 and 700. Springs 1140 and bumpers 1142 and 1144 may improve the mechanical coupling between vibrational air transfer devices 1101 and heat spreader 1120. In some embodiments, springs 1140 and bumpers 1142 and 1144 may at least partially support vibrational air transfer devices 1101. Springs 1140 and bumpers 1142 and 1144 also damp translation or rotation around the axes parallel to the y axes and the z axis, while allowing tilting around an axis parallel to the x axis. Springs 1140 may also provide thermal coupling between vibrational air transfer device 1101 and heat spreader 1120 via thermal conduction.

System 1100 thus shares the benefits of system(s) 400, 500, 600, 700, 800, 900, and/or 1000. Pedestals 1110, springs 1140 and bumpers 1142 and 1144 allow vibrational air transfer devices 1101 to be more robust. In particular, springs 1140 and bumpers 1142 and 1144 may allow system 1100 and/or the connection between vibrational air transfer devices 1101 and heat spreader 1120 to withstand greater impacts/larger shocks. In some embodiments, the mechanical coupling between heat spreader 1120 and vibrational air transfer devices 1101 allows for the system to withstand forces (e.g. shocks) in the ranges described for system 400. Tilting of vibrational air transfer devices 1101 around an axis parallel to the x-axis is still allowed. Consequently, vibrational air transfer devices 1101 and system 1100 may be made significantly more robust without significantly adversely affecting performance.

FIG. 12 depicts an embodiment of active MEMS cooling system 1200 including vibrational air transfer devices 1201 thermally and mechanically coupled to heat spreader 1220. For clarity, FIG. 12 is not to scale. In addition, not all portions of system 1200 may be shown. Although two vibrational air transfer devices 1201 are shown, another number may be present. Vibrational air transfer device 1201 is analogous to systems 100 and 200 and cell 301. Thus, vibrational air transfer device 1201 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 1200 also includes heat spreader 1220 and top plate 1230 having apertures 1232 therein. Heat spreader 1220 may be analogous to heat spreader 122, 202, and/or 302. Top plate 1230 may be analogous to top plate 306. Thus, system 1200 may be analogous to system 300. Operation of vibrational air transfer devices 1201 and system 1200, as well as the dimensions, are analogous to those described herein.

System 1200 includes pedestals 1210, springs 1240, bumpers 1242 and 1244, and fillets 246. Pedestals 1210, springs 1240, bumpers 1242 and 1244, and fillets 246 may combine to mechanically and thermally couple vibrational air transfer devices 1201 to heat spreader 1220 in a manner analogous to couplers 440. Pedestals 1210 are analogous to pedestals 190, 290, 390, 510, 610, 710, 810, 910, 1010, and 1110. In some embodiments, pedestals 1210 are thermally conductive and provide mechanical support for vibrational air transfer devices 1201. For example, pedestals 1210 may be formed of thermally conductive epoxy and/or another thermally conductive silicone. However, pedestals 1210 may not be as mechanically robust as the mechanical coupling provided by couplers 440.

Springs 1240, bumpers 1242 and 1244, and fillets 246 are analogous to springs 740, bumpers 640 and 642, and fillets 540. System 1200 may be viewed as a combination of systems 500, 600 and 700. Springs 1240, bumpers 1242 and 1244, and fillets 246 may improve the mechanical coupling between vibrational air transfer devices 1201 and heat spreader 1220. In some embodiments, springs 1240, bumpers 1242 and 1244, and fillets 246 may at least partially support vibrational air transfer devices 1201. Springs 1240, bumpers 1242 and 1244, and fillets 246 also damp translation or rotation around the axes parallel to the y axes and the z axis, while allowing tilting around an axis parallel to the x axis. Springs 1240 may also provide thermal coupling between vibrational air transfer device 1201 and heat spreader 1220 via thermal conduction.

System 1200 thus shares the benefits of system(s) 400, 500, 600, 700, 800, 900, 1000, and/or 1100. Pedestals 1210, springs 1240, bumpers 1242 and 1244, and fillets 246 allow vibrational air transfer devices 1201 to be more robust. In particular, springs 1240, bumpers 1242 and 1244, and fillets 246 may allow system 1200 and/or the connection between vibrational air transfer devices 1201 and heat spreader 1220 to withstand greater impacts/larger shocks. In some embodiments, the mechanical coupling between heat spreader 1220 and vibrational air transfer devices 1201 allows for the system to withstand forces (e.g. shocks) in the ranges described for system 400. Tilting of vibrational air transfer devices 1201 around an axis parallel to the x-axis is still allowed. Consequently, vibrational air transfer devices 1201 and system 1200 may be made significantly more robust without significantly adversely affecting performance.

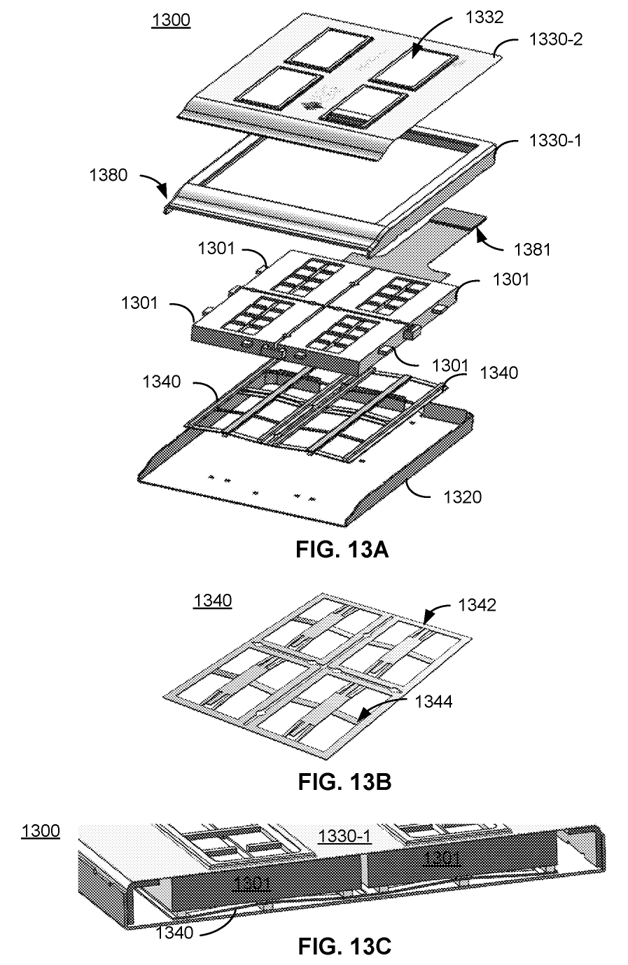

FIGS. 13A-13C depict an embodiment of an active MEMS cooling system 1300 including vibrational air transfer devices 1301 thermally and mechanically coupled to a heat spreader. More specifically, FIG. 13A depicts an exploded view of system 1300. FIG. 13B depicts a perspective view of spring 1340. FIG. 13C depicts a portion of system 1300. For clarity, FIGS. 13A-13C are not to scale. In addition, not all portions of system 1300 may be shown. Although four vibrational air transfer devices 1301 are shown, another number may be present. Vibrational air transfer devices 1301 are analogous to systems 100 and 200 and cell 301. Thus, vibrational air transfer device 1301 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 130, 230, and/or 330, top chamber 140, 240, and/or 340, and bottom chamber 150, 250, and/or 350. System 1300 also includes heat spreader 1320 and top plate 1330 having apertures 1332 therein. Heat spreader 1320 may be analogous to heat spreader 132, 202, and/or 302. Top plate 1330 may be analogous to top plate 306. Thus, system 1300 may be analogous to system 300. Operation of vibrational air transfer devices 1301 and system 1300, as well as the dimensions, are analogous to those described herein.

System 1300 includes pedestals (not shown) and springs 1340 that may combine to mechanically and thermally couple vibrational air transfer devices 1301 to heat spreader 1320 in a manner analogous to couplers 440. Springs 1340 include a frame as well as ribs 1342 that extend along the axis of the cooling elements and cross ribs 1344 that extend perpendicular to the cooling element axis. In some embodiments, springs may at least partially support vibrational air transfer devices 1301. Springs 1340 also damp translation or rotation around the axes parallel to the y axes and the z axis, while allowing tilting around an axis parallel to the x axis. Springs 1340 may also provide thermal coupling between vibrational air transfer device 1301 and heat spreader 1320 via thermal conduction.

System 1300 thus shares the benefits of system(s) 400, 500, 600, 700, 800, 900, 1000, 1100, and/or 1200. Springs 1340 allow vibrational air transfer devices 1301 to be more robust. In particular, springs 1340 may allow system 1300 and/or the connection between vibrational air transfer devices 1301 and heat spreader 1320 to withstand greater impacts/larger shocks. In some embodiments, the mechanical coupling between heat spreader 1320 and vibrational air transfer devices 1301 allows for the system to withstand forces (e.g. shocks) in the ranges described for system 400. Tilting of vibrational air transfer devices 1301 around an axis parallel to the x-axis is still allowed. Consequently, vibrational air transfer devices 1301 and system 1300 may be made significantly more robust without significantly adversely affecting performance.

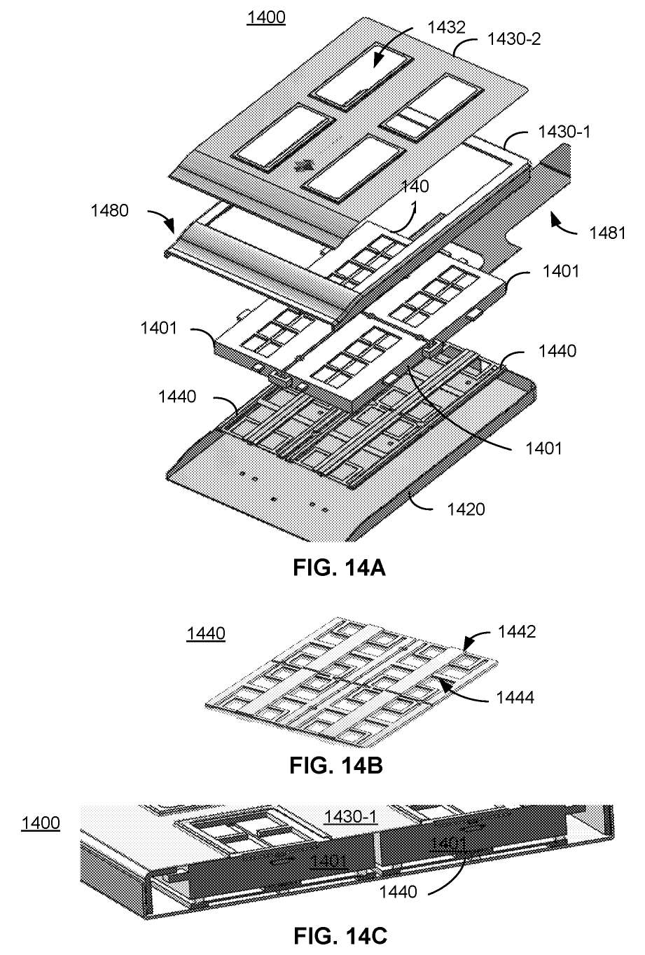

FIGS. 14A-14C depict an embodiment of an active MEMS cooling system 1400 including vibrational air transfer devices 1401 thermally and mechanically coupled to a heat spreader. More specifically, FIG. 14A depicts an exploded view of system 1400. FIG. 14B depicts a perspective view of spring 1440. FIG. 14C depicts a portion of system 1400. For clarity, FIGS. 14A-14C are not to scale. In addition, not all portions of system 1400 may be shown. Although four vibrational air transfer devices 1401 are shown, another number may be present. Vibrational air transfer devices 1401 are analogous to systems 100 and 200 and cell 301. Thus, vibrational air transfer device 1401 may include an actuator in a chamber, a top plate, a bottom plate, a top chamber, and a bottom chamber analogous to actuators 120, 120’, 220, and/or 320, chamber 140/150, 240/250, and/or 340/350, top plate 110, 210, and/or 310, bottom plate 140, 230, and/or 330, top chamber 140, 240, and/or 340, and bottom chamber 150, 250, and/or 350. System 1400 also includes heat spreader 1420 and top plate 1430 having apertures 1432 therein. Heat spreader 1420 may be analogous to heat spreader 142, 202, and/or 302. Top plate 1430 may be analogous to top plate 306. Thus, system 1400 may be analogous to system 300. Operation of vibrational air transfer devices 1401 and system 1400, as well as the dimensions, are analogous to those described herein.

System 1400 includes pedestals (not shown) and springs 1440 that may combine to mechanically and thermally couple vibrational air transfer devices 1401 to heat spreader 1420 in a manner analogous to couplers 440. Springs 1440 include a frame as well as ribs 1442 that extend along the axis of the cooling elements and cross ribs 1444 that extend perpendicular to the cooling element axis. In some embodiments, springs may at least partially support vibrational air transfer devices 1401. Springs 1440 also damp translation or rotation around the axes parallel to the y axes and the z axis, while allowing tilting around an axis parallel to the x axis. Springs 1440 may also provide thermal coupling between vibrational air transfer device 1401 and heat spreader 1420 via thermal conduction.

System 1400 thus shares the benefits of system(s) 400, 500, 600, 700, 800, 900, 1000, 1100, 1200, and/or 1300. Springs 1440 allow vibrational air transfer devices 1401 to be more robust. In particular, springs 1440 may allow system 1400 and/or the connection between vibrational air transfer devices 1401 and heat spreader 1420 to withstand greater impacts/larger shocks. In some embodiments, the mechanical coupling between heat spreader 1420 and vibrational air transfer devices 1401 allows for the system to withstand forces (e.g. shocks) in the ranges described for system 400. Tilting of vibrational air transfer devices 1401 around an axis parallel to the x-axis is still allowed. Consequently, vibrational air transfer devices 1401 and system 1400 may be made significantly more robust without significantly adversely affecting performance.

In fluid transfer systems 400, 500, 500’, 600, 700, 800, 900, 900’, 1000, 1100, 1200, 1300 and 1400 various features are highlighted. However, feature(s) of the embodiments described herein may be combined in manners not specifically depicted herein.

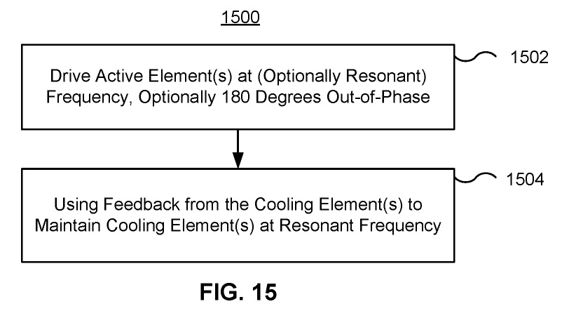

FIG. 15 is a flow chart depicting an embodiment of method 1500 for using an active MEMS fluid transfer system. Method 1500 may include steps that are not depicted for simplicity. Method 1500 is described in the context of fluid transfer systems 400, 500, 500’, 600, 700, 800, 900, 1000, 1100, 1200, 1300, and/or 1400. However, method 1500 may be used with other fluid systems including but not limited to systems and cells (e.g. cooling systems 100, 200, and/or 300) described herein.

One or more of the active elements in a fluid transfer system is actuated to vibrate at 1502. At 1502, an electrical signal having the desired frequency is used to drive the active element(s). In some embodiments, the active elements are driven at or near structural and/or acoustic resonant frequencies at 1502. The driving frequency may be 15 kHz or higher. In some embodiments, the driving signal may be 20 kHz or higher. For example, the frequency may be 22 kHz-26 kHz (e.g. nominally 24 kHz). If multiple active elements are driven at 1502, the active elements may be driven out-of-phase. In some embodiments, the active elements are driven substantially at one hundred and eighty degrees out of phase. Further, in some embodiments, individual active elements are driven out-of-phase. For example, different portions of an active element may be driven to vibrate in opposite directions (i.e. analogous to a seesaw as shown in FIGS. 1E and 1F). In some embodiments, individual active elements may be driven in-phase (i.e. analogous to a butterfly). In addition, the drive signal may be provided to the anchor(s), the cooling element(s), or both the anchor(s) and the active element(s). Further, the anchor may be driven to bend and/or translate.

At 1502, the amplitude of vibration of the active element may be selected such that a gap between the active element and the cushion (or the gap between the cushion and the orifice plate) need not always be maintained. Thus, the amplitude of vibration is set such that crashes may occur. In some embodiments, the driving of the active element at 1502 is configured such that gap is very small (e.g. within 10 micrometers of a crash, within 5 micrometers of a crash, or less) or such that contact (e.g. a light crash) is possible during normal operation. For example, the power provided to the piezoelectric material(s) used to vibrate the active element may be set such that the amplitude of vibration of the active element during normal operation includes some contact between the cushion and the active element (e.g. the active element may touch the cushion) or some contact between the cushion on the active element and the orifice plate. In other embodiments, the power may be set such that a gap between the active element and the cushion (or between the cushion and the orifice plate) is present for normal operation. Thus, contact/crashes may occur, but contact may not be considered part of normal operation. Also at 1502, the active element is energized based on this amplitude.

Feedback from the active element(s) may be used to adjust the driving current, at 1504. In some embodiments, the adjustment is used to maintain the frequency at or near the acoustic and/or structural resonant frequency/frequencies of the active element(s) and/or fluid transfer system. Resonant frequency of a particular active element may drift, for example due to changes in temperature or changes in the active element itself. Adjustments made at 1504 allow the drift in resonant frequency to be accounted for.

For example, actuator 320 may be driven to vibrate at 1502. In some embodiments, actuator 320 is driven at or near resonance. Vibrational motion of actuator 320 draws the fluid through chamber 340/350 and drives fluid out through orifices 332. At 1504, the frequency of vibration of active element 320 may be adjusted using feedback. Thus, active element 320 may be kept at or near resonance.

Using method 1500, the benefits of fluid transfer systems 400, 500, 500’, 600, 700, 800, 900, 1000, 1100, 1200, 1300, 1400, and/or analogous systems may be achieved. In particular, the device with which the fluid transfer system is used may be efficiently cooled. Because the thermal and mechanical coupling between the active fluid transfer device and the heat spreader are maintained, operation is made more robust. Thus, the benefits described herein may be obtained.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a vibrational air transfer device, the vibrational air transfer device extending in space and defining a plane; and
a heat spreader, the vibrational air transfer device being thermally and mechanically coupled to the heat spreader, the mechanical coupling allowing the vibrational air transfer device to tilt with respect to the plane about at least one axis and damping translation of the vibrational air transfer device with respect to the heat spreader.

2. The system of claim 1, wherein the plane is defined by the vibrational air transfer device in a static configuration.

3. The system of claim 1, wherein the mechanical coupling restricts the vibrational air transfer device from tilting around at least one of a second axis at a first nonzero angle from the first axis or a third axis at a second nonzero angle from the axis.

4. The system of claim 1, wherein the vibrational air transfer device is supported and coupled to the heat spreader by a support structure that allows the vibrational air transfer device to tilt with respect to the plane about the at least one axis and damps the translation with respect to the heat spreader.

5. The system of claim 4, wherein the support structure is thermally conductive.

6. The system of claim 4, wherein the support structure includes a pedestal.

7. The system of claim 4, wherein the support structure includes at least one of bumpers, springs or fillets.

8. The system of claim 7, wherein the at least one of the bumpers, springs and fillets has a hardness of at least A20 and not more than A60 on a Shore A hardness scale.

9. The system of claim 1, wherein the mechanical coupling between the heat spreader and the vibrational air transfer devices allows for the system to withstand forces of at least 400 multiplied by g, where g is a surface gravity force of earth.

10. The system of claim 1, wherein the vibrational air transfer device includes a chamber having an actuator therein, the actuator vibrating around an actuator axis substantially parallel to the at least one axis.

11. A system, comprising:
a vibrational air transfer device, the vibrational air transfer device extending in space and defining a plane, the vibrational air transfer device including a plurality of chambers, each of the plurality of chambers having a cooling element therein;
a heat spreader;
a plurality of pedestals coupling the vibrational air transfer device to the heat spreader; and
a plurality of mechanical supporting structures coupled with the plurality of pedestals and the heat spreader, the plurality of pedestals and the plurality of mechanical supporting structures allowing the vibrational air transfer device to tilt with respect to the plane about at least one axis and damping translation of the vibrational air transfer device with respect to the heat spreader, the cooling element vibrating around a cooling element axis parallel to the at least one axis.

12. The system of claim 11, further comprising:
a plurality of additional mechanical supporting structures coupled with the vibrational air transfer device and the heat spreader, the plurality of additional mechanical supporting structures allowing the vibrational air transfer device to tilt with respect to the plane about the at least one axis and damping translation of the vibrational air transfer device with respect to the heat spreader.

13. The system of claim 11, wherein the plane is defined by the vibrational air transfer device in a static configuration.

14. The system of claim 11, wherein the plurality of pedestals and the plurality of mechanical supporting structures allow vibrational air transfer device to tilt by not more than thirty degrees around the at least one axis and restrict the vibrational air transfer device from pitching and yawing from the at least one axis.

15. The system of claim 11, wherein at least one of the plurality of pedestals or the plurality of mechanical supporting structures is thermally conductive.

16. The system of claim 11, wherein plurality of mechanical supporting structures each has a hardness of at least A20 and not more than A60 on a Shore A hardness scale.

17. The system of claim 11, wherein the plurality of pedestals and the plurality of mechanical supporting structures allow for the system to withstand forces of at least 400 multiplied by g, where g is a surface gravity force of earth.

18. A method, comprising:
driving an active element of a vibrational air transfer device to induce a vibrational motion at a frequency, the vibrational motion driving fluid through the vibrational air transfer device, the vibrational air transfer device extending in space and defining a plane, the vibrational air transfer device being thermally and mechanically coupled to a heat spreader, the mechanical coupling allowing the vibrational air transfer device to tilt with respect to the plane about at least one axis and damping translation with respect to the heat spreader.

19. The method of claim 18, wherein the mechanical coupling restricts the vibrational air transfer device from tilting around at least one of a second axis at a first nonzero angle from the first axis or a third axis at a second nonzero angle from the axis.

20. The method of claim 18, wherein the mechanical coupling between the heat spreader and the vibrational air transfer device allows for a connection between the heat spreader and the vibrational air transfer device to withstand forces of at least 400 g, where g is the local gravity of the earth.
